(19) United States
(12) Patent Application Publication
(10) Pub. No.: US 2008/0208496 A1
(43) Pub. Date: Aug. 28, 2008

(54) Device for identifying consumer devices in an electric network and process for operating the device

(76) Inventors: Thomas Habath, Berlin (DE); Reyk Brandalik, Heinersdorf (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/529,556

(22) Filed: Sep. 29, 2006

Related U.S. Application Data
(60) Provisional application No. 60/721,969, filed on Sep. 30, 2005.

(30) Foreign Application Priority Data
Sep. 30, 2005 (DE) 10 2005 047 901.4

(51) Int. Cl. G01R 23/16; G01R 29/00

(52) U.S. Cl. 702/77; 702/57

(57) ABSTRACT

The invention relates to a device for identifying consumer devices in an electric network (1) with currents that can vary over time and said device has a measuring device (3) for measuring at least one current signal of the electric network on at least one measuring point, a storage medium (5) in which at least one consumer spectrum, determined in advance, is stored, a data analysis device (6) and an output device (7). In this case, the data analysis device (6) converts the measured current signals of the electric network (1) into a network signal, automatically generates a model in which the network signal can be linked with at least one consumer signal, stored in advance in the storage medium (5), of at least one consumer device (2a, 2b), and automatically analyzes the model for determining at least one consumer distribution in the electric network.

The invention relates, moreover, to a process for operating the device.

With the device according to the invention and the process, it thus is possible to identify, in a simple and precise way, the consumer device and the consumer distribution in an electric network by a single measurement.

This application claims the benefit of the filing date of U.S. Provisional Application Ser. No. 60/721,969 filed Sep. 30, 2005.

The invention relates to a device for identifying consumer devices in an electric network and a process for operating the device.

In an electric network, for example an electric energy supply network in which a host of consumer devices are interconnected in a network, the current that flows through a consumer device and is influenced by said consumer device can create feedback that is in contact with the electric network at a feeder point. This effect is referred to in general as network feedback and is caused by the direct influence of the current and the voltage by the consumer device in the electric network. The network feedback caused by the consumer device in this case is determined by the type of consumer device in the electric network.

One effect of the network feedback is that in an electric network in which at one point feedback is in contact with a sinusoidal fundamental oscillation, the current that flows in the branches of the electric network is not purely sinusoidal and thus cannot be described by an oscillation with a single frequency. In this case, the current produces harmonic oscillations in the electric network that disadvantageously influence the shape of current and voltage at the feeder point but also at the site of the consumer device.

Harmonic oscillations can in principle be divided into harmonic and interharmonic harmonic oscillations. Harmonic oscillations (also referred to as harmonics for short) have frequencies that are integral multiples of the basic frequency. Interharmonic harmonic oscillations, however, have frequencies that are unlike the integral multiples of the basic frequency. Harmonic frequencies can be produced, for example, by consumer devices with a non-linear current-voltage characteristic, for example a diode. Interharmonics are produced, however, for example in the case of switching processes that are not synchronized with the basic frequency of the voltage.

Harmonic oscillations in the current of an electric network produce distortion of the current and can thus result in problems in the electric network, in particular for the consumer device connected to the electric network. By the non-sinusoidal current uptake of the network, a non-sinusoidal voltage drop is produced at the feeder point of the network, such that the feedback that is in contact at the feeder point is distorted and forms harmonic oscillations. Such harmonic oscillations are picked up by the consumer devices on the network and can shorten the operation and the service life of the consumer device. The latter is problematic, for example, for consumer devices that have stringent precision requirements, for example precision measuring devices, medical systems or the like, which are considerably impaired in their function by the distortions in the electric network used in the energy supply.

In this case, the problems that are described occur in particular in the electric networks that are designed as energy supply networks. In the last decades, the meaning of such energy supply networks for worldwide energy supply has gained enormous importance, whereby the need for electric energy has increased steadily and to a disproportionate extent to the world population. In this case, the type, distribution and number of consumer devices in energy supply networks have changed in recent years and have produced a magnification of network feedback, i.e., distortion of currents and voltages in the energy supply networks. This has resulted in that in recent years, boundary values for the distortion in energy supply networks could not be maintained, and the probability of consumer failures, primarily in the industrial realm, has increased steadily.

To be able to affect predictions on distortion of currents and voltages in an electric network to reduce or to compensate for network feedback, it is advantageous to determine precisely the consumer device distribution in the electric network, i.e., the proportions by percentage of different consumer devices in the electric network.

The object of this invention is to make available a device and a process with which consumer devices in an electric network, which produce distortions of currents and voltages in the electric network, can be identified in a precise and simple way, and/or the consumer distribution in the electric network can be determined.

This object is achieved according to the invention by a device with the features of claim 1.

In this case, it is provided according to the invention that a device for identifying consumer devices in an electric network with currents that can vary over time has
a measuring device for measuring at least one current signal on at least one measuring point of the electric network,
a storage medium in which at least one consumer signal, determined in advance, is stored,
a data analysis device that
   converts at least one measured current signal into a network signal,
   automatically generates a model in which the network signal can be linked to at least one consumer device with at least one consumer signal that is stored in advance in the storage medium,
   automatically analyzes the model for determining at least one consumer distribution of the consumer devices in the electric network, and
an output device for at least one consumer distribution.

The device according to the invention allows the determination of the consumer distribution of the consumer devices in the electric network based solely on consumer signals that are detected and stored in the storage medium and the detected network signal of the electric network. To detect the network signal, the current signal of the electric network is measured by means of the measuring device at one measuring point and is converted into the network signal by the data analysis device. The data analysis device generates a model from the detected network signal and from consumer signals stored in a storage medium, and in said model the network signal is linked to the consumer signals and is analyzed for identification of the consumer devices, in particular the discrete consumer distribution of the consumer devices in the electric network. As a consumer signal, reference is made here to the signal of a current picked up by a consumer device when observing only the consumer device (without the influence of the other consumer devices in the electric network). The consumer distribution indicates which consumer devices with which proportions in the electric network are present and is discrete, substantiated by the finite number of consumer devices present.

An essential advantage of the device according to the invention is that by means of the device, the consumer devices arranged in an electric network can be determined by a simple measurement of a current signal at a measuring point of the electric network.

The current signal that is measured by the measuring device is preferably a time signal. The network signal, which is derived from the current signal, can be, however, either a time signal or a network spectrum that represents a frequency signal. Like the network signal, the consumer signal can also be either a time signal or a frequency signal that represents a consumer spectrum. If time signals are used, the consumer signals and the network signal, which are linked in the model, encompass sequences of current measuring values at different times that characterize the flow of current through the consumer device or at the measuring point of the electric network. If frequency signals, i.e., consumer spectra and a network spectrum, are used to generate the model, the consumer signals and the network signal encompass the frequency portions of the current in the consumer devices or at the measuring point of the electric network. In this case, the frequency signals and the time signals are linked to one another via a Fourier transform.

The data analysis mechanism of the device is preferably designed such that it has means for identifying the consumer device in the electric network, by means of which a network spectrum that represents the network signal can be determined from a measured current signal of the electric network, or the network signal is formed in the time realm by suitable synchronization and normalization. The measurement of the current signal that is carried out in this case in the electric network that is to be measured thus represents the actual measurement that can, if necessary, be repeated any number of times. Based on the thus determined network spectrum or the time network signal and with incorporation of consumer spectra or time consumer signals that produce consumer signals that are determined in advance and stored in a database, the consumer distribution of the consumer devices in the electric network is then determined.

If the current signal of the electric network is a time signal and frequency signals to generate the model are to be used, the data analysis device determines the network spectrum by a Fourier transform from the measured current signal of the electric network. In this case, the data analysis device can have in particular means for performing an FFS (Fast Fourier Transform), which makes possible an efficient performance of the conversion of the current signal in the network spectrum.

The data analysis device advantageously has means for generating the model, by means of which at least one consumer spectrum or the time consumer signal and the network spectrum or the time network signal can be linked in an equation system. In the data analysis device, a setting-up of an equation system, in which the consumer spectra or time consumer signals that are stored in advance in the storage medium and the measured network spectrum or the time network signal participate, thus is carried out. This equation system is analyzed and, in this way, the consumer distribution, i.e., the distribution in percentage of the consumer device in the electric network, is determined.

According to the invention, the device has a storage medium, in which the consumer signals of different consumer devices are stored. In this case, the device preferably has an additional measuring device, by means of which the consumer signals of the consumer device are detected before the actual measurement and are stored in the storage medium in the form of a database. For this purpose, the measuring device can be connected to the storage medium and matches the detected consumer signals to the database of the storage medium. This measuring device is thus used in the detection of consumer signals of consumer devices before the actual measurement. In this case, it is not necessary that the consumer devices for detecting the consumer signals be located in the same electric network in which the detection of the network signal takes place. It is conceivable that one or more consumer devices are detected in one or more separate networks before the beginning of the actual measurement, the consumer signals of the consumer devices are stored in the database, and the consumer distribution of these detected consumer devices is then determined in another electric network. The measuring device for detecting the consumer signals thus is used to generate a database, which is stored in the storage medium of the device. In this case, the measuring device can be designed as a separate measuring device, which is used exclusively in the detection of the consumer signals. It is also conceivable, however, to use the same measuring device to detect the consumer signals as for later detection of the network signals.

The measuring device for detecting the consumer signals advantageously has a means by means of which the current signal of at least one consumer device can be measured and the consumer signal can be determined from the current signal. The measuring device thus determines the consumer signal of the consumer device from a measured current signal of a consumer device and forwards the latter to the storage medium.

In this case, the measuring device for detecting one or more consumer signals can be constituted such that it receives a time current signal, Fourier-transforms the latter, and thus the consumer signal is determined from the measured current signal.

After a consumer signal is acquired, matching to the database filed in the storage medium is carried out. In this case, the measuring device for detecting the consumer signals can have means by means of which a classification of the consumer devices based on the detected consumer signals in consumer classes is carried out. For this purpose, any detected consumer signal is compared to other consumer signals that are stored in the database, whereby consumer devices with similar consumer signals are assigned to a consumer class that encompasses several consumer devices.

It is conceivable that the measuring device for detecting the consumer signals is a mobile measuring device, which can be connected to the storage medium for matching to the database that is stored in the storage medium but otherwise can be operated separately from the other components of the device. A thus designed measuring device makes possible a flexible use and a simple handling of the device, in particular for initializing detection of various consumer signals.

In an advantageous embodiment, the device for measuring the current signal of the electric network is connected to a measuring point of the electric network. In this case, it is conceivable that the device is connected securely to the electric network and thus is a component of the network. This is advantageous if a long-term repeated identification of the consumer device in the electric network is desired.

In another configuration, the device is integrated in a compact measuring device that can be arranged in a stationary manner on an electric network and can be connected to the latter or can be designed as a mobile measuring device for variable use in different electric networks. In this case, the device can be added to an already existing measuring device in particular as a component that determines the consumer distribution of consumer devices in an electric network and thus can produce an expansion of an existing measuring device.

In an advantageous configuration of the invention, the device has a compensation device that works together with the data analysis device for compensating a distortion of currents and voltages in an electric network such that the currents and the voltages in the electric network can be matched in a desired way. In this case, the compensation device is connected to the electric network or is integrated in the electric network, determined from the consumer distribution compensation parameters determined from the data analysis device, and it thus acts on the current and the voltage in the electric network, such that a desired current or a desired voltage is set at least on the site of one or more consumer devices. The compensation device thus produces feedback for regulating the electric network: the network signal is determined from the measured current signal, in turn the consumer distribution is derived from the network signal, and the compensation parameters necessary for compensation of the network are determined from the consumer distribution, with which then the compensation device performs a compensation of the electric network.

Many possibilities of use of the device according to the invention are conceivable.

For example, the device can be used to determine the consumer devices in an energy supply network. The device can then determine the consumer distribution of consumer devices in the energy supply network, and the current and voltage feed into the energy supply network can vary based on the consumer distribution of the consumer devices such that distortions in the current and in the voltage of the energy supply network are reduced and the harmonic oscillations in the energy supply network are compensated.

It is also conceivable that the device is used for monitoring and/or for controlling a system with an electric network and consumer devices arranged in the electric network. Based on the determined consumer distribution, the device can then determine and indicate malfunctions in one or more of the consumer devices, thus replace separate sensors of a sensor system to monitor the system. For example, the use of the device for monitoring a production system or production line or an electric industrial network that has electric machines, for example a factory or the like, is conceivable. The device then determines the consumer distribution of the system or production line at one time. If deviations in a consumer distribution that is defined as normal are identified, it can be assumed that there is a malfunction of one or more of the consumer devices and in which consumer this malfunction is present can be determined simultaneously from the consumer distribution.

The object is achieved, moreover, by a process with the features of claim 19. According to the invention, the process has the following steps:
Measurement of at least one current signal of an electric network at least one measuring point,
Determination of a network signal from at least one measured current signal of the electric network,
Automatic generation of a model in which the network signal and at least one consumer signal of at least one consumer device that is acquired in advance are linked to one another,
Automatic analysis of the model for identifying the consumer device in the electric network,
Storage and/or output of a discrete consumer distribution in the electric network.

With the process according to the invention for operating the device according to one of claims 1 to 18, first the current signal of an electric network is measured at a measuring point. Then, the current signal is converted into the network signal, whereby the conversion is carried out by means of a Fourier transform at a time current signal and a network signal that is formed as a network spectrum. From the thus detected network signal and the consumer signals stored in a database of a storage medium, a model is then generated in which the network signal is linked to the consumer signals and which is analyzed to determine the consumer distribution. In a final step, the consumer distribution is then stored or output by means of an output device.

By means of the process according to the invention, the determination of the consumer distribution of the consumer devices in the electric network thus is possible in a simple and precise way, whereby the measurement of the network signal at a measuring point of the electric network is sufficient to determine the consumer devices in the electric network.

The consumer signals of the consumer devices are advantageously produced as discrete vectors that are arranged in a consumer matrix to generate the model. From the measured network signal, which also produces a vector, and the consumer matrix, an equation system is then formed that is analyzed to identify the consumer devices in the electric network and from which the consumer distribution is determined. Depending on whether the network signal and the consumer signals are time signals or frequency signals, the vectors of the network signal and the consumer signals encompass the current values at the measuring point of the electric network or in the consumer devices at discrete times or the current amplitudes in the case of discrete frequencies.

The consumer signals of one consumer device or several consumer devices are preferably detected in advance, i.e., before the beginning of the regular measuring operation, in an initialization phase, and they are stored in a storage medium in the form of a database. In this case, the consumer signals must be detected only once. If the relevant consumer devices are detected in the database, additional measurements are unnecessary for determining additional consumer signals.

Various processes for detecting the consumer spectra are conceivable.

On the one hand, to determine the consumer signal of a consumer device, the current signal of the consumer device can be measured separately in advance, whereby the consumer device, to ensure a disruption-free, exact measurement, should be considered in as isolated an environment as possible. This detection is, as explained above, only necessary one time for each consumer device.

On the other hand, it is possible and advantageous, for the detection of consumer signals, to detect different network signals at different times and to derive the consumer signals from these different, detected network signals. This has the advantage that no separate measurement of the individual consumer devices in an isolated environment is necessary, but rather the consumer signals in a connected arrangement of the consumer devices in the electric network can be determined. In particular, it thus is also possible to perform a constant adjustment and an updating of the database of the consumer signals stored in the storage medium based on the network signals even during the actual measurement in an electric network.

In the last-mentioned case, the determination of the consumer signals from the network signals that are to be measured at different times is preferably carried out by means of an eigenvalue analysis or a singular value separation by the network signals being arranged in a matrix and analyzed.

The detection of the consumer signals is preferably performed repeatedly, and the database of the storage medium is constantly updated and adapted.

In the generation of the database, it may be advantageous to assign an individual consumer class to consumer devices with similar consumer signals, whereby the consumer signal of the consumer class is produced from the consumer signals of the consumer devices assembled in the consumer class. This has the advantage that, on the one hand, the generation of the model for identifying the consumer devices in the electric network is simplified, and, on the other hand, the consumer distribution can be determined with more precision. The classification of the consumer devices in consumer classes is, moreover, also physically useful, since consumer devices with similar consumer signals also exert similar feedback on the electric network.

The similarity of two consumer signals is determined, in this case, via the correlation of the consumer signals. It is suitable to categorize consumer signals with a normalized correlation coefficient of greater than 0.9, in particular greater than 0.95, as similar and to assign a common consumer class.

The classification of the consumer devices in consumer classes is preferably carried out automatically, iteratively and adaptively, such that the consumer classes are changed with repeated matching to the database, the classification in consumer classes is newly evaluated with each adjustment, and the database is adapted by measurements that are staggered over time.

Advantageously, the consumer signals of the consumer devices produce consumer spectra, and the network signal of the electric network produces a network spectrum, whereby in the consumer spectra and in the network spectrum, the amplitudes of the harmonic oscillations of the current signals of the consumer device or the electric network are stored. Discrete vectors are thus produced as a representation of the consumer spectra and the network spectrum.

In this case, only the uneven harmonic oscillations of the current signals of the consumer devices and the electric network in the model are advantageously taken into consideration. This makes possible a generation of the model in the case of minimum storage requirement and allows an efficient analysis of the model.

Based on the number of consumer devices and the number of harmonic oscillations detected in the consumer spectra and the network spectrum, in this case an under-determined, a determined or an over-determined equation system can be produced. The solution of the equation system then corresponds to the desired consumer distribution of the consumer device in the electric network.

Based on the embodiments shown in the following figures, the basic idea of the invention is to be further explained in more detail. Here:

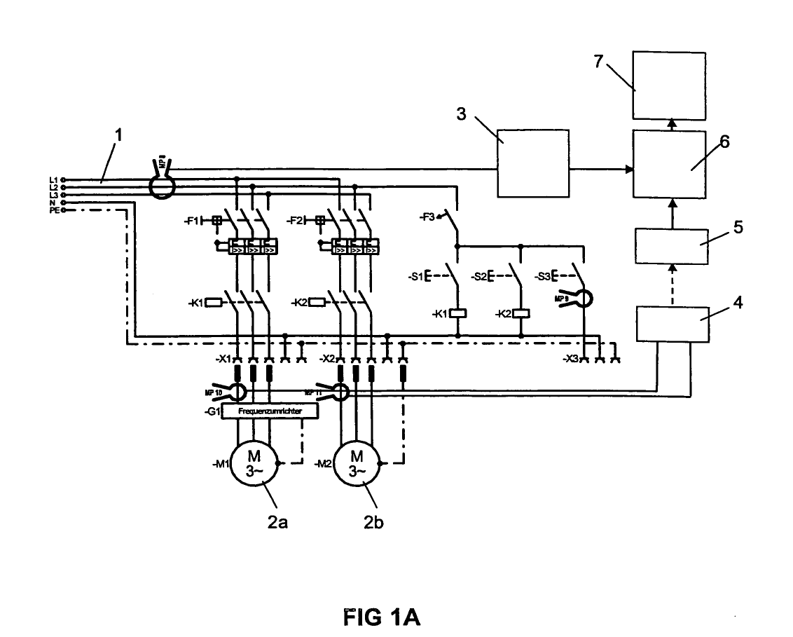

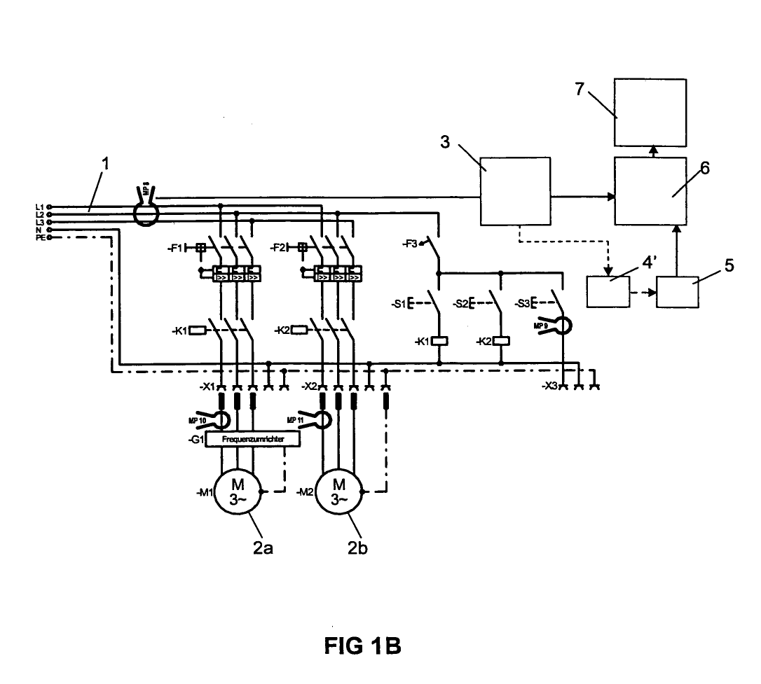

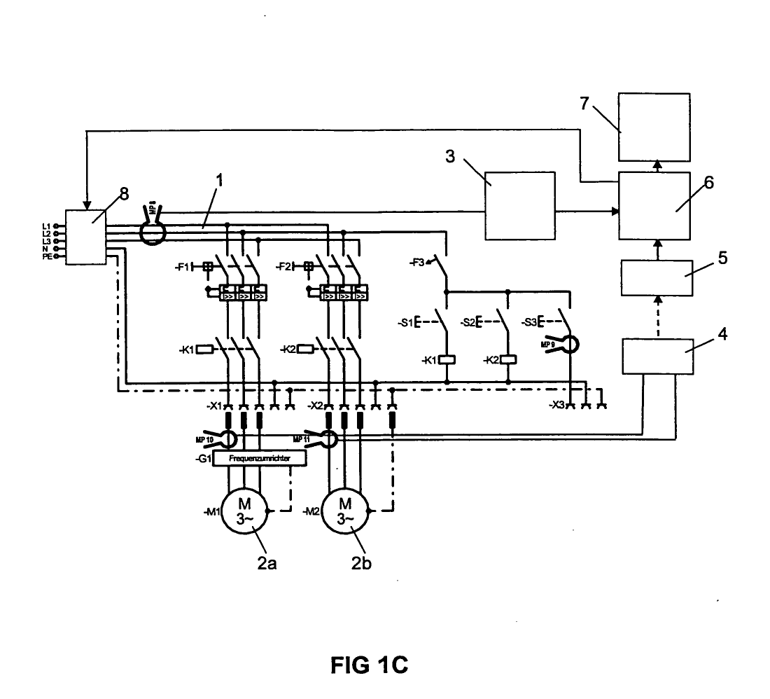

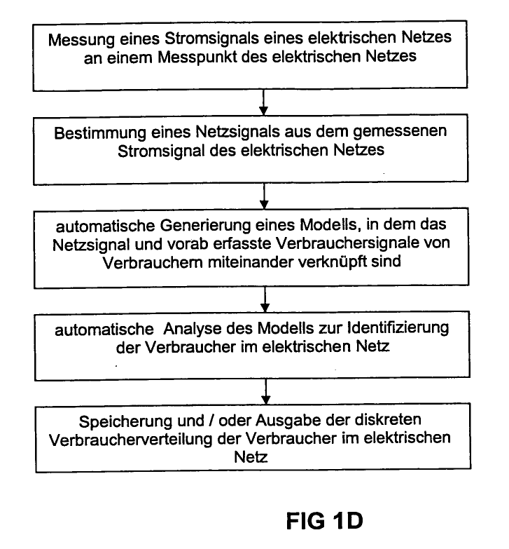

FIGS. 1A, B, C show schematic views of devices for identifying consumer devices in an electric network;

FIG. 1D shows a flow chart of a process for identifying a consumer distribution of consumer devices in an electric network;

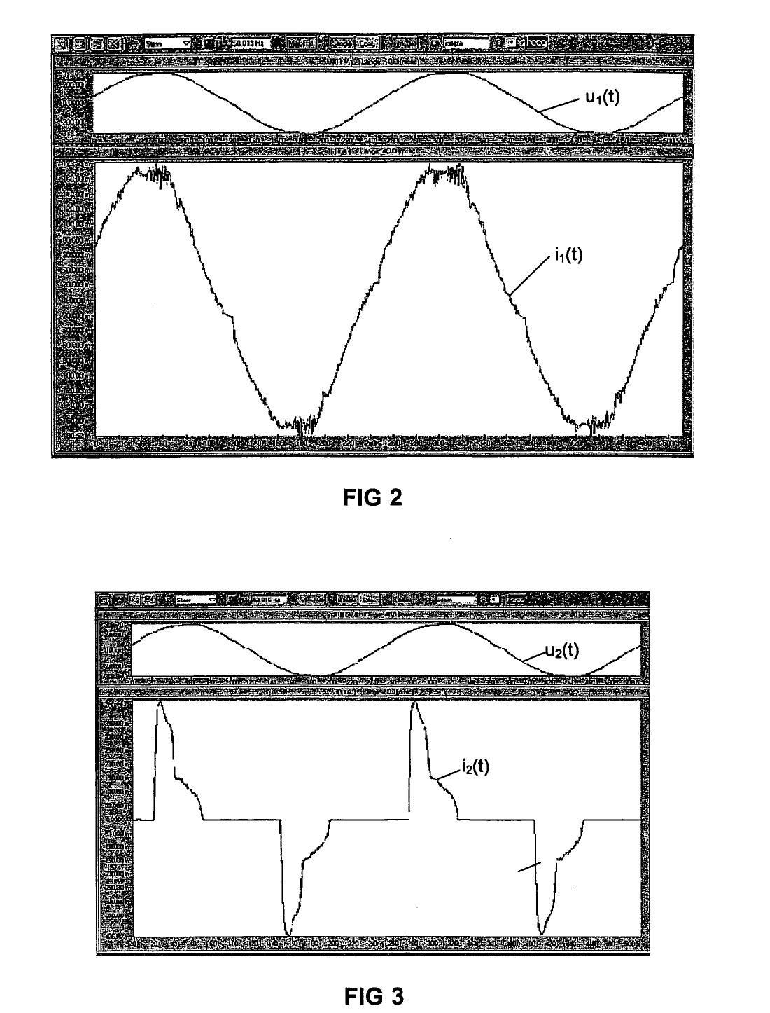

FIG. 2 shows a diagram of the voltage and current plots on a T5 fluorescent lamp with an electronic ballast (EVG);

FIG. 3 shows a diagram of the voltage and current plot of an energy-efficient lamp;

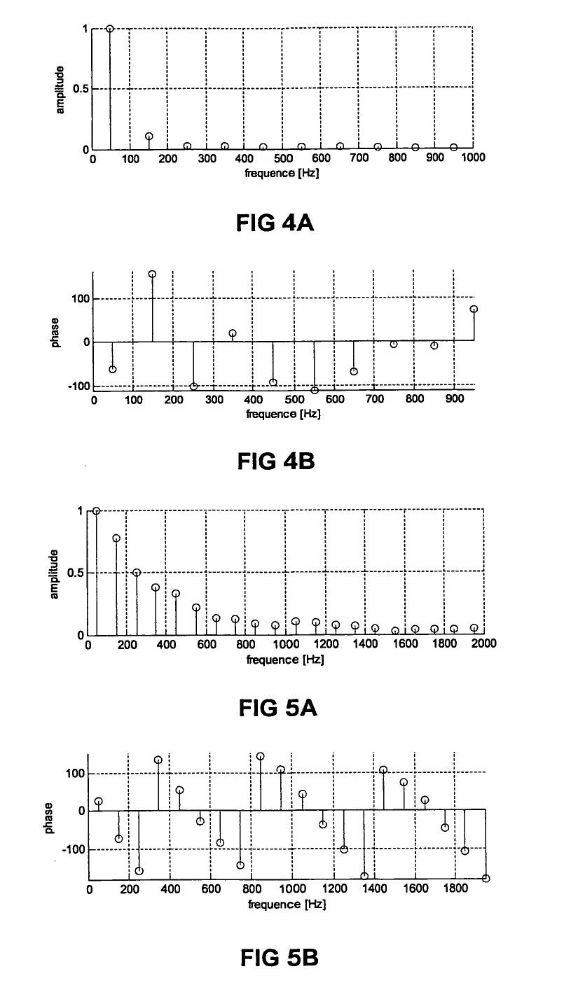

FIGS. 4A, B show the consumer spectrum that represents the consumer signal (value and phase) of a T5 fluorescent lamp with an electronic ballast (EVG);

FIGS. 5A, B show the consumer spectrum that represents the consumer signal (value and phase) of an energy-efficient lamp;

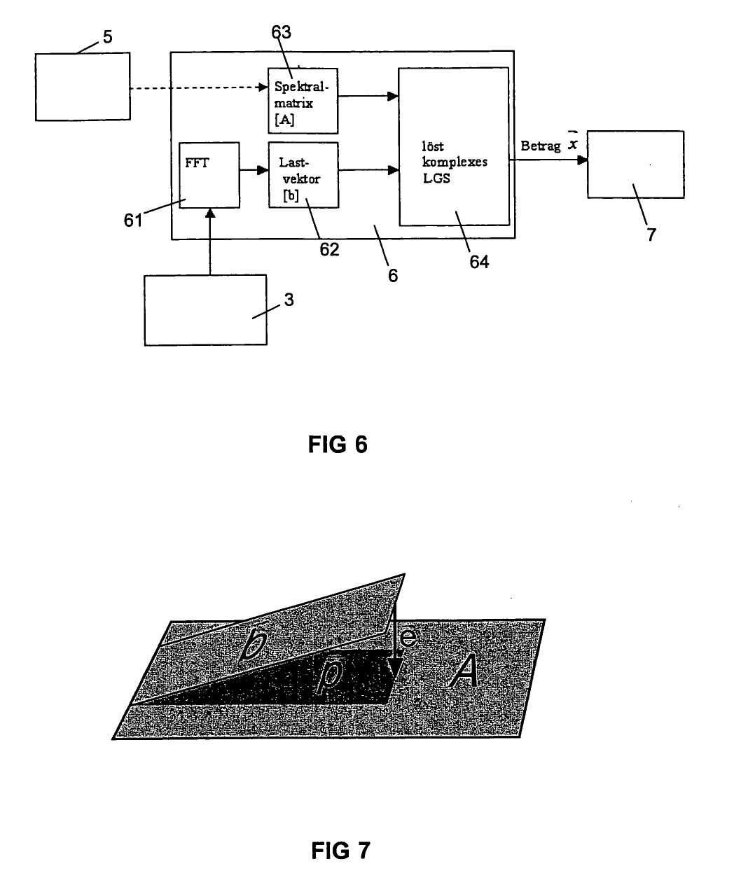

FIG. 6 shows a schematic detail view of the device for identifying consumer devices in an electric network;

FIG. 7 shows a schematic visualization of the projection of the network spectrum b in the consumer matrix A;

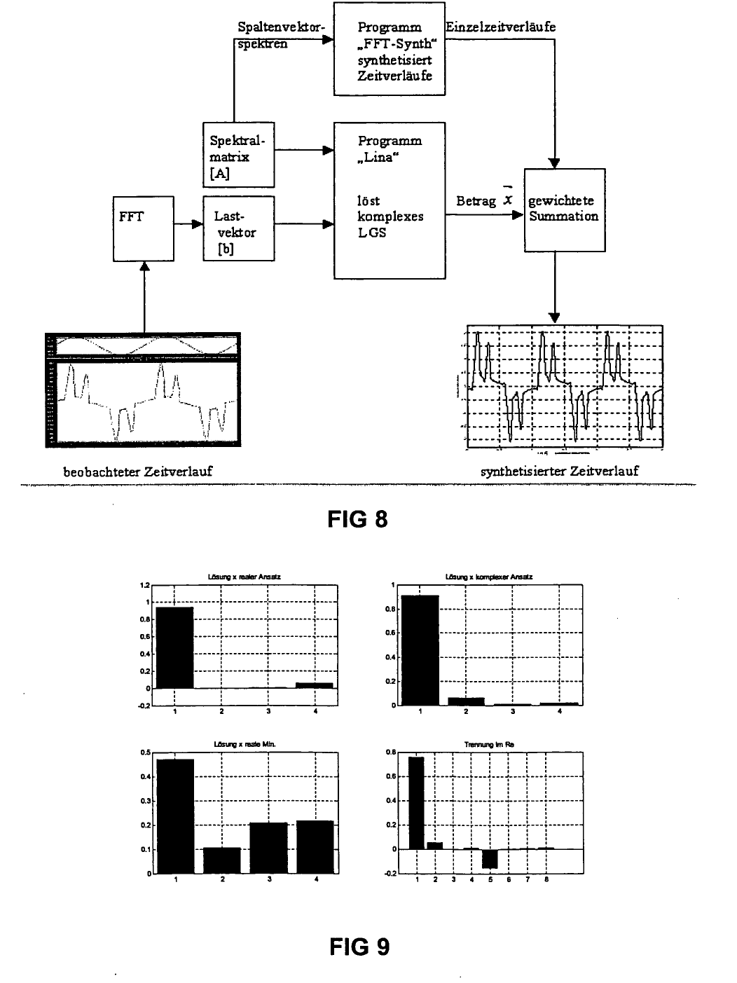

FIG. 8 shows a schematic flow chart of the Fourier synthesis for review of the determined consumer distribution;

FIG. 9 shows a diagram of a first calculated consumer distribution according to different sets of solutions;

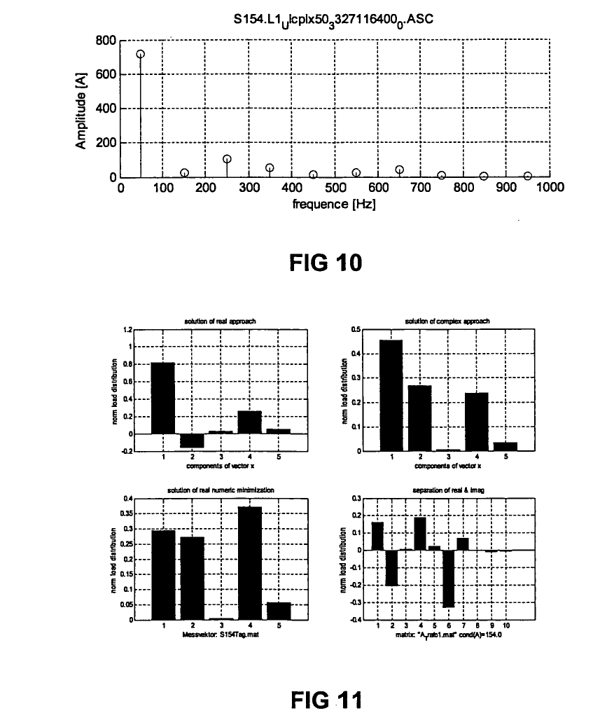

FIG. 10 shows a diagram of a detected network spectrum;

FIG. 11 shows a diagram of a second calculated consumer distribution according to the different sets of solutions;

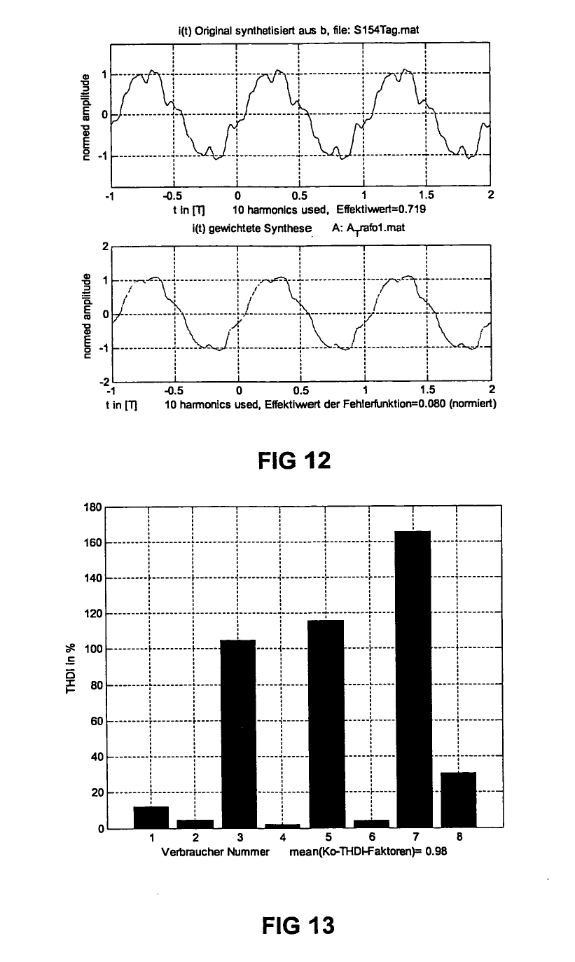

FIG. 12 shows a diagram of the measured current signal of an electric network and the current signal that is specified by means of Fourier synthesis from the determined consumer distribution, and

FIG. 13 shows a diagram that shows measured THD(I) values of eight different consumer devices.

### 1 Device

In FIGS. 1A, 1B and 1C, different configurations of the device according to the invention are depicted. The devices according to the invention have a measuring device 3, a storage medium 5, a data analysis device 6 and an output device 7. The measuring device 3 is connected via a measuring point MP 8 to the electric network 1, which has power lines L1, L2, and L3 via which electric energy is fed into the network and is supplied to consumer devices 2a, 2b. Other components of the electric network are switches S1, S2, and S3, control devices K1 and K2, and safety devices F1 and F2.

The idea according to the invention is implemented here based on the device in which the consumer distribution of consumer devices in an electric network is determined from detected network spectra or consumer spectra that represent network signals and consumer signals. The network spectra and the consumer spectra in this case represent the frequency proportions of the currents at a measuring point of the electric network or in the consumer devices. In a similar way, however, instead of these frequency signals, time signals, i.e., time network signals and consumer signals, could be used that encompass the current values at different times at the measuring point of the electric network or in the consumer devices and thus characterize the electric network or the consumer devices. The time signals are connected to the frequency signals via a Fourier transform and contain the same information as the frequency signals.

In a first embodiment of the invention according to FIG. 1A, the device has a measuring device 4 that is connected via measuring points MP10 and MP11 to consumer devices 2a, and 2b and is used to detect consumer spectra that represent consumer signals in an initializing advance measurement to generate a database.

To identify the consumer devices in the electric network, first the consumer spectra of one or more consumer devices 2a, 2b are determined by means of the measuring device 4 and are filed in a database in the storage medium 5. This measurement is carried out only one time before the beginning of the actual measurement and is used to generate the database and to detect the consumer devices 2a, 2b that are to be identified. In this case, it is not necessary that the consumer devices 2a, 2b be connected to detect the consumer spectra with the electric network 1 that is to be measured, i.e., are arranged in the actual electric network 1. Rather, it is advantageous to detect the consumer devices 2a, 2b individually in advance in an isolated environment and thus to determine the consumer spectra.

FIGS. 2 and 3 show two current signals i₁(t), i₂(t), measured by way of example, of two different consumer devices (a fluorescent lamp with an electronic ballast (EVG) in FIG. 2 and an energy-efficient lamp in FIG. 3), which describe the response of the consumer devices to excitation by a sinusoidal voltage u₁(t), u₂(t). From these current signals of the individual consumer device measured by means of the measuring device, the measuring device 4 determines the consumer spectra by means of a Fourier transform. The consumer spectra of the fluorescent lamp with an electronic ballast (EVG) and the energy-efficient lamp are depicted in FIG. 4A, B or 5A, B, whereby the complex consumer spectra in each case have value and phase that are depicted in a bar diagram. In this case, discrete harmonic oscillations are detected in each consumer spectrum. The extreme left bar in each case represents the amplitude or the phase of the fundamental oscillation, while the bar arranged on the extreme right indicates the amplitude or phase of the 10^{th} harmonic. In the consumer spectra that are shown, only the amplitudes and the phases of the uneven harmonic oscillations in the consumer spectra according to FIGS. 4A, B and 5A, B are filed in order to minimize the storage space requirement and the computing expense, and they are stored in the storage medium 5 in a database.

Another configuration of the device, which is distinguished from the device according to FIG. 1A in the means for detecting the consumer spectra, is depicted in FIG. 1B. In the device according to FIG. 1B, the detection of the consumer spectra is carried out in advance by means of the measurement of current signals at the measuring point MP8, which converts network spectra that are derived from the analysis device 4′ into network signals and are stored in a matrix. From network spectra that are detected and are different and that are arranged in a matrix, the analysis device then determines the consumer spectra of the consumer devices 2a, 2b in the electric network 1 and stores the latter in the storage medium 5. The determination of the consumer spectra from the detected network spectra in this case can be carried out in the analysis device 4′ by means of an eigenvalue analysis, whereby the eigenvectors produce the individual consumer spectra. The advantage of this configuration is that the consumer devices 2a, 2b do not have to be considered separately in an isolated environment, and a permanent matching to the database can also take place during the actual measurement.

In both embodiments of the device according to FIGS. 1A and 1B, the plots of the actual measurement for identifying the consumer devices 2a, 2b in the electric network 1 are identical. In a detail view, FIG. 6 shows the plot carried out in the data analysis device for identification of the consumer devices in the electric network. The measuring device 3 measured the current signal at the measuring point MP8 of the electric network 1. The data analysis device 6 converts the current signal, measured by the measuring device 3, into a component 61 that depicts a means for performing a Fourier transform, by means of a Fourier transform in the network spectrum that represents the network signal. In addition, the data analysis device 6 has means 62, 63, and 64 that generate the model from the network spectrum and the consumer spectra that file the storage medium 5 in the database, whereby the network spectrum represents a load vector and forms a linear equation system together with the consumer spectra that are arranged in the consumer matrix A. The means 62, 63 in this case produce components in which the consumer matrix and the network spectrum are intermediately stored. In the component 64, the data analysis device 6 triggers the equation system and thus determines the consumer distribution that is forwarded as vector x to the output device 7. The basic plot of the process, which is embodied in an electric network by the device for identifying the consumer device, is illustrated schematically in FIG. 1D.

The data analysis device can advantageously be formed by a computing device. The individual components 61, 62, 63, and 64 are then implemented in the computing device, and the process is carried out, for example, as software with use of the components of the computing device. As software for implementing the process for identifying the consumer device in an electric network, known programs, for example the Matlab program (The Mathworks, USA), are then presented.

FIG. 1C shows a third embodiment of the device, which essentially has the same components as the device according to FIG. 1A, in which, however, in addition a compensation device 8 is integrated, which is arranged connected in series in the electric network 1. The compensation device 7 is connected to the data analysis device 6, and the determined consumer distribution in the form of a vector x is obtained from the data analysis device 6. Based on the vector x, the compensation device determines compensation parameters, by means of which the currents and voltages in the electric network are matched in the desired way. For example, the compensation device can contain non-linear active or passive structural elements, which are set up and configured by means of the compensation parameters.

### 2 Model

Below, the generation and the analysis of the model are explained in detail. In this case, the model is described below based on frequency signals, i.e., a network spectrum that represents the network signal and consumer spectra that represent consumer signals.

Sources of the harmonic oscillations are consumer devices with a non-sinusoidal current uptake that produces a current signal, i.e., all consumer devices with structural elements with a nonlinear current-voltage characteristic such as iron chokes or semiconductor elements. The latter are present, for example, in power converter systems for drives, in heating systems or switching power supplies of home electronic devices, e.g., television devices or computers. Consumer devices with asymmetrical and widely varying phase loads, such as, e.g., electric arc furnaces and welding machines, are also producers of harmonic oscillations.

In an electric network, a host of different consumer devices, for example PCs, computer-controlled laboratory devices, lighting systems with partially dimmable fluorescent lamps or drives that are speed-controlled by frequency converters, can be arranged. The latter are present in ventilation systems, conveyor belt systems and in process engineering, e.g., in the case of agitator drives and flow regulators. Often, the electric network is also prestressed, such that the voltage prevailing in the electric network is already distorted and additional harmonic oscillations develop in the current signal.

In principle, two types of consumer devices are distinguished, namely linear and nonlinear consumer devices.

Linear Consumer Devices These consumer devices have an ohmic, inductive and/or capacitive behavior with a sinusoidal current signal and do not produce any harmonic oscillations.
Nonlinear Consumer Devices In the case of a consumer device with a basically sinusoidal current signal, but which is connected in any form so that the current signal of the consumer device is manipulated periodically or non-periodically in its amplitude, harmonic oscillations are produced that, on the one hand, can be distinctly harmonic or—if the current plot is manipulated by the consumer device in an asynchronous manner with respect to the fundamental oscillation—interharmonic. Typical consumer devices that produce interharmonic harmonic oscillations are power converters, direct converters for three-phase motors, or oscillation packet controls. Primarily signal devices, such as audio-frequency powerline control systems, can be disrupted by interharmonic harmonic oscillations, and even flickers can be triggered.

### 2.1 Theoretical Considerations on Superpositions of Harmonic Oscillations

In an electric network, consumer classes that comprise a consumer device or several consumer devices contribute in different ways to the distortion of the current signal of the electric network. In this case, the current signal is determined by superposition of the current signals of the individual consumer devices:

$${I}_{n} = {\sum }_{i = 2}^{m} {I}_{n , i} * {e}^{{jϕ}_{n , i}} \qquad ( 2 \text{-} 1 )$$

whereby m indicates the number of consumer devices and n indicates the harmonic oscillation that is considered.

From Equation 2-1, it follows that the harmonic oscillation contributions of the individual consumer devices can be superposed both destructively and constructively. A destructive superposition is carried out when the harmonic oscillation contributions are reverse-phase, and a constructive superposition is carried out when the harmonic oscillation contributions are in-phase. In addition, the superposition depends on the site of the measuring point in the electric network. In this case, the phase position of the measured signals at the measurement site is decisive and can very well be different from the phase position at the consumer site. The distortion of the current signal of an electric network is generally indicated by the distortion factor, which results in:

$${k}_{gesamt} = \sqrt{{\sum }_{n = 1}^{m} {k}_{n}^{2}} \qquad ( 2 \text{-} 2 )$$

[Key:]

gesamt=total

whereby kₙ refers to the distortion factor of the n^{th} consumer device, and k_{gesamt} refers to the distortion factor of the electric network at the measuring point.

### 2.2 Modeling by Complex Frequency Vector Linear Combination

In an electric network with consumer devices that are connected in parallel and spatial expansion that is disregarded for the time being, the currents in the main branch are added. In this case, the periodic currents can be described completely by their Fourier transform. Based on the property of linearity of the Fourier transform

F(f₁(t)+f₂(t)+ . . . +fₙ(t))(jω)=F₁(jω)+F₂(jω)+ . . . +Fₙ(jω) (2-3)

the process can start from a linear superposition of the consumer spectra of the individual consumer devices. In this case, the large number of different consumer devices can be classified in a readily understood number n of consumer classes, whereby the consumer devices of one consumer class have a similar consumer spectrum and a consumer class is characterized by a single consumer spectrum.

The consumer spectrum of a consumer device (or a consumer class) j is present as a column vector:

$${\vec{F}}_{j} = ( \begin{matrix}{\overline{a}}_{11} \\ {\overline{a}}_{21} \\ ⋮ \\ {\overline{a}}_{m j}\end{matrix} ) \qquad ( 2 \text{-} 4 )$$

whereby āᵢⱼ is the complex amplitude of the i^{th} harmonic considered of the j^{th} consumer device. The currents of the consumer devices are superposed at a linkage point, and thus the network spectrum b is produced based on the linearity of the Fourier transform:

$$( \begin{matrix}{\overline{a}}_{11} \\ {\overline{a}}_{21} \\ ⋮ \\ {\overline{a}}_{m 1}\end{matrix} ) + ( \begin{matrix}{\overline{a}}_{12} \\ {\overline{a}}_{22} \\ ⋮ \\ {\overline{a}}_{m 2}\end{matrix} ) + ... + ( \begin{matrix}{\overline{a}}_{1 n} \\ {\overline{a}}_{2 n} \\ ⋮ \\ {\overline{a}}_{mn}\end{matrix} ) = ( \begin{matrix}{b}_{1 abs} \\ {b}_{2 abs} \\ ⋮ \\ {b}_{m abs}\end{matrix} ) = ( \begin{matrix}{\sum }_{j = 1}^{n} {\overline{a}}_{1 j} \\ {\sum }_{j = 1}^{n} {\overline{a}}_{2 j} \\ ⋮ \\ {\sum }_{j = 1}^{n} {\overline{a}}_{mj}\end{matrix} ) \qquad ( 2 \text{-} 5 )$$

Normalization If, instead of the measured absolute consumer spectrum of each consumer device, the consumer spectrum that is normalized to the fundamental oscillation is used,

$${\vec{F}}_{j\_norm} = \frac{1}{\vert {\overline{a}}_{1 j} \vert} ( \begin{matrix}{\overline{a}}_{11} \\ {\overline{a}}_{21} \\ ⋮ \\ {\overline{a}}_{m j}\end{matrix} ) = ( \begin{matrix}{\overline{a}}_{1 j} \\ {\overline{a}}_{2 j} \\ ⋮ \\ {\overline{a}}_{m j}\end{matrix} ) \qquad ( 2 \text{-} 6 )$$

the specific consumer spectrum or frequency vector can be mentioned. If the latter is used in Equation 2-5, the following linear equation system is obtained.

$${x}_{1} ( \begin{matrix}{a}_{11} \\ {a}_{21} \\ ⋮ \\ {a}_{m 1}\end{matrix} ) + {x}_{2} ( \begin{matrix}{a}_{12} \\ {a}_{22} \\ ⋮ \\ {a}_{m 2}\end{matrix} ) + ... + {x}_{n} ( \begin{matrix}{a}_{1 n} \\ {a}_{2 n} \\ ⋮ \\ {a}_{mn}\end{matrix} ) = ( \begin{matrix}{b}_{1 abs} \\ {b}_{2 abs} \\ ⋮ \\ {b}_{m abs}\end{matrix} ) \qquad ( 2 \text{-} 7 )$$

The factors x₁, x₂, . . . , xₙ then correspond to the desired consumer distribution of the consumer devices in the electric network.

If the network spectrum b that is determined from the measured current signal of the electric network is normalized analogously to Equation 2-6, a normalized equation system and, in x, the normalized consumer distribution of the consumer devices in an electric network are obtained, whereby the components have x values in the range of between 0 and 1.

$${x}_{1} ( \begin{matrix}{a}_{11} \\ {a}_{21} \\ ⋮ \\ {a}_{m 1}\end{matrix} ) + {x}_{2} ( \begin{matrix}{a}_{12} \\ {a}_{22} \\ ⋮ \\ {a}_{m 2}\end{matrix} ) + ... + {x}_{n} ( \begin{matrix}{a}_{1 n} \\ {a}_{2 n} \\ ⋮ \\ {a}_{mn}\end{matrix} ) = ( \begin{matrix}{b}_{1} \\ {b}_{2} \\ ⋮ \\ {b}_{m}\end{matrix} ) \qquad ( 2 \text{-} 8 )$$

After the conversion into matrix notation, Equation 2-8 has the following configuration.

$$\underbrace{( \begin{matrix}{a}_{11} & {a}_{12} & & {a}_{1 n} \\ {a}_{21} & … & & {a}_{21} \\ … & & … & \\ … & & & … \\ {a}_{m 1} & … & … & {a}_{mn}\end{matrix} )}_{A} * \underbrace{( \begin{matrix}{x}_{1} \\ {x}_{2} \\ ⋮ \\ ⋮ \\ {x}_{m}\end{matrix} )}_{\vec{x}} = c \underbrace{( \begin{matrix}{b}_{1} \\ {b}_{2} \\ ⋮ \\ ⋮ \\ {b}_{m}\end{matrix} )}_{\vec{b}} ⇔ A \vec{x} = \vec{b} \\ A ∈ {R}^{mxn} ; x , b ∈ {R}^{m} \qquad ( 2 \text{-} 9 )$$

m is the number of harmonics considered, and n is the number of basic consumer devices (or consumer classes). The vector b is the network spectrum, which is determined from the current signal of the electric network 1 that is measured by the measuring device 3, and the vector x corresponds to the desired consumer distribution of the consumer devices 2a, 2b in the electric network. Viewed in mathematical terms, the consumer matrix A is only a subspace of the n-dimensional space owing to the absence of orthogonality and is formed by its column vectors that represent the consumer spectra. They can be viewed as the “frequency distribution space of the current in a point of linkage.” Independently of what combination of consumer devices is directly present at this point, the vector of the measured network spectrum is always found within this specific frequency distribution space. Thus, with this preparation and knowing the consumer devices (or the consumer classes encompassing several consumer devices), the superposition of all defined consumer devices is described.

Time Signals When using time signals instead of the network spectrum and the consumer spectra, i.e., a time network signal and time consumer signals, in which current values at the measuring point of an electric network or in the consumer devices at different times are stored, an equation system that is analogous to Equation 2-9 is produced. If, in Equation 2-9, the column vectors of matrix A are replaced by the corresponding time consumer signals that are linked to the consumer spectra via a Fourier transformation according to Equation 2-3 and the network spectrum b of the right side by the time network signal, the formulation of the equation system is thus obtained for time signals. In this case, the normalization of the consumer signals is carried out such that the effective value of the time signals is exactly 1. The column vectors of the consumer signals then read:

$${{I}^{->}}_{j\_norm} = \frac{1}{\sqrt{{\sum }_{i = 1}^{m} {a}_{ij}^{2}}} ( \begin{matrix}{\overline{a}}_{1 j} \\ {\overline{a}}_{2 j} \\ ⋮ \\ {\overline{a}}_{mj}\end{matrix} ) = ( \begin{matrix}{a}_{1 j} \\ {a}_{2 j} \\ ⋮ \\ {a}_{mj}\end{matrix} ) \qquad ( 2 \text{-} 10 )$$

The network signal b of the right side is also normalized analogously. The sets of solutions described below for solving the equation system according to Equation 2-9 can also be applied analogously when using time signals.

### 2-3 Correction in the Case of Spatially Extensive Networks

The preparation shown in the preceding section requires a negligible delay of the currents in the electric network based on the special expansion of the electric network. If the expansion cannot be disregarded, the following ways to consider the latter exist:
1. The consumer devices are measured within the electric network with incorporation of the path lengths between consumer devices and measuring points and are defined as column vectors. As a result, possible phase distortions in the measuring results are already contained in the matrix and thus do not appear to be errors.
2. The specific spectra must be provided with a frequency vector delay correction.
   Frequency Vector Delay Correction A time delay by the spatial expansion of the electric network does not result in an identical phase shift of the harmonics of the current signals, i.e., there is no corresponding phase rotation of all components of a frequency vector. Each component of the vector becomes an inherent phase rotation.

$${\vec{F}}_{j} = ( \begin{matrix}{a}_{1 j} \\ {a}_{2 j} \\ ⋮ \\ {a}_{mj}\end{matrix} ) = ( \begin{matrix}\vert {a}_{1 j} \vert {e}^{j ω t} {e}^{{ϕ}_{1}} \\ \vert {a}_{2 j} \vert {e}^{j 3 ω t} {e}^{{ϕ}_{3}} \\ ⋮ \\ \vert {a}_{mj} \vert {e}^{j 19 ω t} {e}^{{ϕ}_{19}}\end{matrix} ) = ( \begin{matrix}\vert {a}_{1 j} \vert {{e}^{j ω t +}}^{{ϕ}_{1}} \\ \vert {a}_{2 j} \vert {e}^{j 3 ω t + {ϕ}_{3}} \\ ⋮ \\ \vert {a}_{mj} \vert {{e}^{j 19 ω t +}}^{{ϕ}_{19}}\end{matrix} ) \qquad ( 2 \text{-} 11 )$$

The first term of the e-function represents the rotation of the vectors. The latter rotate exactly with the basic frequency or with multiples thereof for the harmonics of a higher order and thus are irrelevant for frequency representation. The second term represents the phase shift and is therefore indicated together with the amount in a complex vector representation in the frequency range.

$${\vec{F}}_{j} = ( \begin{matrix}\vert {a}_{1 j} \vert {{e}^{j}}^{{ϕ}_{1}} \\ \vert {a}_{2 j} \vert {{e}^{j}}^{{ϕ}_{3}} \\ ⋮ \\ \vert {a}_{mj} \vert {{e}^{j}}^{{ϕ}_{19}}\end{matrix} ) \qquad ( 2 \text{-} 12 )$$

With this representation, calculations can be done as with the normal complex consumer spectra. In the case of a delay in the time realm based on the finite propagation speed in the network, however, there is an additional phase shift, in which the factor e^{jwΔt}=e^{jφ}^{_{d}} results as a phase shift from the time delay Δt=T_{d} in the time realm. If the entire frequency vector of a consumer device is delayed, the phase-shifting factor for any component must be calculated separately.

$${\vec{F}}_{j} ( \vec{f} ( t - d ) ) ( \vec{ω} ) \neq ( \begin{matrix}\vert {a}_{1 j} \vert {{e}^{j}}^{{ϕ}_{1}} \\ \vert {a}_{2 j} \vert {{e}^{j}}^{{ϕ}_{3}} \\ ⋮ \\ \vert {a}_{mj} \vert {{e}^{j}}^{{ϕ}_{19}}\end{matrix} ) {e}^{{jϕ}_{d}} \qquad ( 2 \text{-} 13 )$$

If n is the rank of the harmonics, which is assigned to the i^{th} component of the frequency vector j, then a time shift must be treated as follows:

$${\vec{F}}_{d ; j} ( \vec{f} ( t - d ) ) ( \vec{ω} ) = \underbrace{( \begin{matrix}{a}_{1 j} & 0 & ⋯ & 0 \\ 0 & {a}_{2 j} & ⋰ & ⋮ \\ ⋮ & ⋰ & ⋱ & 0 \\ 0 & 0 & ⋯ & {a}_{mj}\end{matrix} )}_{IF} \underbrace{( \begin{matrix}{{e}^{j}}^{{n}_{{1}^{ϕ} d}} \\ {e}^{j {n}_{{2}^{ϕ} d}} \\ ⋮ \\ {e}^{j {n}_{{m}^{ϕ} d}}\end{matrix} )}_{Phasenkorrekturvektor} \qquad ( 2 \text{-} 14 )$$

### Phase Correction Vector

In this case, an exponential correction vector yields a complex, exponential correction factor that makes it possible to assign a separate phase correction to each component of the consumer spectrum of a consumer device. This connection applies, however, only in the case of the frequency-independent propagation speed of the current, i.e., in dispersion-free conductors. If this is not the case, the different operating time of the frequencies must be determined and introduced into the correction vector. If Δvₙ is the propagation speed difference of the n^{th} harmonic relative to the 50 Hz current and Iⱼ is the removal of the j^{th} consumer device from the measuring site, the delay correction is expanded as follows:

$${\vec{F}}_{j} ( f ( t - d ) ) ( \vec{ω} ) = ( \begin{matrix}{a}_{1 j} & 0 & ⋯ & 0 \\ 0 & {a}_{2 j} & ⋰ & ⋮ \\ ⋮ & ⋰ & ⋱ & 0 \\ 0 & 0 & ⋯ & {a}_{mj}\end{matrix} ) ( \begin{matrix}{e}^{j {n}_{1 ( {ϕ}_{d} + ωΔ {v}_{m} {l}_{j} )}} \\ {e}^{j {n}_{2 ( {ϕ}_{d} + ωΔ {v}_{n 2} {l}_{j} )}} \\ ⋮ \\ {e}^{j {n}_{m ( ( ϕ d + ωΔ {{v}_{n}}_{m} {l}_{j} )}}\end{matrix} ) \qquad ( 2 \text{-} 15 )$$

Since the determination of the dispersion is difficult, the error that is produced by dispensing with the corrections must be determined. If the relative propagation speed of the currents in the electric networks relative to the light speed is vᵣ and the maximum permissible phase shift is Δφ, the maximum permissible line length is produced by:

$${l}_{max} = {v}_{r} c \frac{Δϕ}{2 π} \frac{1}{{f}_{max}} whereby {v}_{r} is the equation for light speed . \qquad ( 2 \text{-} 16 )$$

In time signals, a correction is not carried out by means of a correction factor to compensate a phase, but rather by means of a time shift of the signals, whereby the time shift is produced directly from the time delay as a result of the line length difference between the consumer devices.

Example of an Error by Spatial Expansion If, e.g., with vᵣ=0.66 and 2 KHz as the maximum frequency in the spectrum (40^{th} harmonic), a reliable phase tolerance of π/50 is assumed, a maximum permissible line length of 1 km is produced. The phase error that is derived from the delay linearly decreases with the frequency and therefore plays a role only in the consideration of higher-rank harmonics.

The calculated permissible maximum line length relates only to the line length difference between various consumer devices of a consumer class below one another or to the line length difference between the consumer device and the measuring point of the electric network in the operation. The error introduced by the line length difference at the measuring point of the electric network for a consumer class can be completely eliminated, however, by the determination of the consumer classes at the measuring point of the electric network being carried out. Thus, all phase shifts of the harmonics already contain the consumer devices and the consumer classes in the specific consumer spectrum.

### 2.4 Solution of the Complex Equation System

To set up the equation A\vec{x}=\vec{b}, in general more harmonic oscillations that are evaluated as consumer classes are present, such that an over-determined, complex, linear equation system (LGS) is produced that has either one or even no solution corresponding to an actual LGS. Exactly one solution is obtained if the vector b is located within the column subspace of A, i.e., if b can be formed from a true linear combination of the column vectors. This situation generally does not arise in reality since
1. The vector b is the network spectrum that is formed from the measured current signal of the electric network at the measuring point and thus is associated with measuring errors,
2. To form consumer classes in which individual consumer devices are combined, tolerances are defined and tolerated in the deviation of consumer spectra of the individual consumer devices,
3. The white noise in the measuring devices forms a statistically evenly-divided error,
4. A statistically evenly-divided quantization error is produced by the scanning performed in the measuring devices for measuring a current signal,
5. And consumer devices that do not belong to a defined class can be turned on.

The solvability of an over-determined LGS can be determined mathematically by the rank of matrix A. If the rank of matrix A is equal to the rank of the matrix that is expanded by the vector b, exactly one solution exists. In this case, the vector b that represents the network spectrum of the electric network depends in a linear fashion on the column vectors and thus is part of the subspace of A. In mathematical terms, the latter can be expressed as follows:

rank(A)=rank(A/b) [symbol] Ax=b has a clear solution (2-17)

In this connection, the column rank is the same as the line rank and this corresponds to the number of consumer devices. An example of this can be seen in the following section.

Example of Solvability As an example, the rank of matrix A (formed from the measured consumer spectra of two consumer devices) and that of its expanded matrix (A/b) was examined. In this case, the vector b is the network spectrum produced by the superposition of these two consumer devices.

$$\begin{matrix}rank ( \begin{matrix}0 , 99726 - 0 , 07397 i & 0 , 73525 + 0 , 6778 i \\ 0 , 03709 + 0 , 20957 i & - 0 , 01205 - 0 , 0030316 i \\ - 0 , 80988 - 0 , 26564 i & 0 , 02393 + 0 , 02515 i \\ 0 , 59912 + 0 , 17081 i & - 0 , 00813 + 0 , 0093073 i \\ 0 , 03649 + 0 , 09231 i & - 0 , 00092 + 0 , 00045077 i \\ - 0 , 29684 - 0 , 20344 i & 0 , 00200 - 0 , 0016949 i \\ 0 , 13632 + 0 , 07692 i & - 0 , 00082 - 0 , 00062151 i \\ 0 , 05893 + 0 , 00951 i & - 0 , 00077 + 0 , 00034278 i \\ - 0 , 09818 + 0 , 02798 i & 0 , 00027 + 0 , 00090452 i \\ 0 , 034843 - 0 , 04126 i & - 0 , 00033 + 9 , 655 e - 005 i\end{matrix} ) = 2 & ( 2 \text{-} 18 ) \\ rank ( \begin{matrix}0 , 99726 - 0 , 07397 i & & & 0 , 73525 - 0 , 67789 i & 0 , 73516 - 0 , 67789 i \\ 0 , 03709 + 0 , 20957 i & & & - 0 , 012050 - 0 , 0030 i & - 0 , 00327 - 0 , 06846 i \\ - 0 , 80988 - 0 , 26564 i & & & 0 , 023930 + 0 , 02515 i & - 0 , 51000 - 0 , 072017 i \\ 0 , 59912 + 0 , 17081 i & & & - 0 , 00818 + 0 , 00930 i & 00 , 37772 + 0 , 15698 i \\ 0 , 03649 + 0 , 09231 i & & & - 0 , 000922 + 0 , 00045 i & - 0 , 00079 - 00 , 023322 i \\ - 0 , 29684 - 0 , 20344 i & & & 0 , 002006 - 0 , 001690 i & - 0 , 170980 - 0 , 09899 i \\ 0 , 13632 + 0 , 07692 i & & & - 0 , 000826 - 0 , 000620 i & 0 , 116570 + 0 , 06157 i \\ 0 , 05893 + 0 , 00951 i & & & - 0 , 000775 + 0 , 00031 i & - 0 , 016639 - 0 , 0020653 i \\ - 0 , 09811 + 0 , 02795 i & & & 0 , 0002736 + 0 , 0009 i - & 0 , 042881 + 0 , 013143 i \\ 0 , 03484 - 0 , 041269 i & & & - 0 , 0003317 + 9 , 6 e - 5 i & 0 , 046343 - 0 , 030897 i\end{matrix} ) = 3 & ( 2 \text{-} 19 )\end{matrix}$$

The rank of the expanded matrix (A/b) is greater than the rank of matrix A, although the vector b up to a real linear normalization factor is the measuring result of the physical superposition of the two column vectors of the matrix A. An addition with subsequent normalization of the first two columns in this case produces a vector that is very similar to the vector b but not to the vector b. The Euclidean norm of the error vector between the sum of the column vectors and the measuring vector is a yardstick of the measuring error here. The equation system thus is not clearly solvable for b.

For analysis, the linear equation system according to Equation 2-9 thus must be approximately solved. Below, different attempts to analyze the equation system are described.

Projection of b in the Subspace A The idea of the projection is to find a vector p that is located in the column subspace of A and that comes closest to vector b. This vector corresponds to the orthogonal projection of b to A. The relationship of vectors b and p is illustrated in FIG. 7.

The equation system that is formed by incorporation of the projection p

A\vec{x}=\vec{p} (2-20)

is clearly solvable. In this case, the vector p is determined by the projection matrix P, which rotates the vector b in the subspace of A and is scaled to the length of its orthogonal projection.

\vec{p}=P\vec{b} (2-21)

To determine the projection matrix P, first the difference of the vectors b and p, which corresponds to the vector e (error) and is perpendicular to A and thus also perpendicular top because of the orthogonal properties of the projection, is considered.

\vec{e}=\vec{b}−\vec{p} (2-22)

Since e is perpendicular to the subspace formed by A, it follows that:

A^{T}\vec{e}=\vec{0} (2-23)

It thus holds true that

A^{T}(b−Ax)=0 [symbol] A^{T}b=A^{T}AX (2-24)

It follows from the above that:

[A^{T}A]⁻¹A^{T}\vec{b}=\vec{x} (2-25)

If both sides are now multiplied by A, the projection matrix P is produced:

$$\begin{matrix}Ax = {A [ {A}^{T} A ]}^{- 1} {A}^{T} b ⇒ p = \underbrace{{A [ {A}^{T} A ]}^{- 1} {A}^{T} b}_{P} & ( 2 \text{-} 26 ) \\ P = {A [ {A}^{T} A ]}^{- 1} {A}^{T} & ( 2 \text{-} 27 )\end{matrix}$$

The projection matrix P thus projects the vector b in the column space of A. The desired solution in x then follows:

x=[A^{T}]⁻A^{T}b (2-28)

If A and b are complex, the transpose of a matrix A^{T} must be replaced by the hermitic A^{H} in Equation 2-28. In this case, Equation 2-28 corresponds to the “least square” set of solutions known from the measuring technology.

For the complex case, there follows the solution: x,bεC^{m}; AεC^{m×n}

x=[A^{H}A]⁻¹A^{H}b (2-29)

Expansion in the Case of the Under-Determination The solution that is shown is only valid for the case AεC^{m×n}, m≧n; rank(A)=n, i.e., if A has the full rank (column rank). If several consumer devices (or consumer classes) are to be identified as detected harmonics, an under-determined equation system results. Such an equation system also has no clear solution, but rather infinitely many solutions. In this case, which is referred to as “rank defect” or “singular compensating problem,” it is suggested to find the solution vector with the smallest length. To this end, the matrices U and V are defined as follows.

$$\begin{matrix}U = [ \begin{matrix}orthogonale \\ Eigenvektoren \\ von : {A}^{T} A\end{matrix} ] & V = [ \begin{matrix}orthogonale \\ Eigenvektoren \\ von : {A}^{T} A\end{matrix} ] \\ [ orthogonal eigen \text{-} & [ orthogonal eigen \text{-} \\ vectors of : {A}^{T} A ] & vectors of : {AA}^{T} ]\end{matrix} \qquad ( 2 \text{-} 30 )$$

In addition, A=USV^{T} can be a singular value separation of A.

The solution of the smallest length is then defined as:

x⁺=VS⁺U^{T}b=A⁺b (2-31)

The matrix A⁺ is the pseudoinverse or Moore-Penrose inverse of A. It is the natural generalization of the inverse of a regular matrix. The latter always solves a linear equation system (LGS) and is an option for the calculation of the consumer distribution x.

In summary, the following cases are produced, which all can be solved by means of the Moore-Penrose inverses:

1. If A is regular: x is the clear solution, such as x=A⁻¹b

2. If the LGS is over-determined: x is the “least square” solution

3. In the case of a rank defect: x is “the shortest-length solution”

In the third case, inaccuracy in the calculated consumer distribution can arise in this case based on the degree of the rank defect.

### 2.4.1 Amplitude Value Spectrum Approach

It is conceivable that the use of certain measuring devices makes possible the determination exclusively of the values of the spectra. In the case, despite the actually complex nature of the consumer spectra and the network spectrum, only the values of the consumer devices formed by the consumer spectra go into the matrix A and the network spectrum b in the equation \vec{x}=inv[A′A]A′\vec{b}.

Inaccuracies can occur, however, in the solving of the equation system by the insignificance of the phase information in the detection exclusively of the values of consumer spectra and the network spectrum.

### 2.4.2 Complex Spectrum Approach

If a measuring device yields complex consumer and/or network spectra, the complex LGS is set up. In this connection, it is to be noted that instead of the transpose of A, the Hermitian of A goes into the equation system.

\vec{x}=[A^{H}A]⁻¹A^{H}\vec{b} (2-32)

In this case, the solution x can be both real and complex. If b is a real superposition of the column vectors, i.e., a truly real weighting, then the solution is real and can be interpreted. If the solution is not real, the value of the components of x can be formed for interpreting the solution and can be interpreted in the electric network as a consumer division of the consumer devices.

### 2.4.3 More Real Approach by Separation of Imaginary and Real Portions

Since x describes the consumer distribution, in portions, of the consumer devices in the electric network, x should be real-valued. It is conceivable, for determining x, to approximate the complex superposition of the consumer spectra by a real x, i.e., to find a pure real x, in which the quadratic distances of the complex numbers on the left and right side of equation system A\vec{x}=\vec{b} have a minimum.

\vec{a}ⱼεC^{m} can be the column vector of the j^{th} column of the matrix A, and xⱼεR.

$$\underbrace{re ( \vec{b} ) + i ( im ( \vec{b} ) ) = {x}_{1} ( re ( {\vec{a}}_{1} ) ) + {x}_{2} ( re ( {\vec{a}}_{2} ) ) + ... + {x}_{n} ( re ( {\vec{a}}_{n} ) )}_{real} + i \underbrace{( {x}_{1} ( im ( {\vec{a}}_{1} ) ) + {x}_{2} ( im ( {\vec{a}}_{2} ) ) + ... + {x}_{n} ( im ( {\vec{a}}_{n} ) ) )}_{im} \qquad ( 2 \text{-} 33 )$$

The vector x can be determined as follows:

$${ar g {min}_{\vec{x}} \vert \vert Re ( ( A ) ) \vec{x} - \vec{b} \vert}^{2} + {\vert Im ( ( A ) ) \vec{x} - \vec{b} \vert}^{2} \vert \qquad ( 2 \text{-} 34 )$$

In this respect, an analytical equation system can be set up in turn.

$$( \begin{matrix}Re ( A ) \\ Im ( A )\end{matrix} ) \vec{x} = ( \begin{matrix}Re ( \vec{b} ) \\ Im ( \vec{b} )\end{matrix} ) \qquad ( 2 \text{-} 35 )$$

This equation system can be solved analytically by the projection of the right side on the now real subspace of the matrix A of the left side:

$$\vec{x} = {[ {( \begin{matrix}Re ( A ) \\ Im ( A )\end{matrix} )}^{T} * ( \begin{matrix}Re ( A ) \\ Im ( A )\end{matrix} ) ]}^{- 1} * {( \begin{matrix}Re ( A ) \\ Im ( A )\end{matrix} )}^{T} * ( \begin{matrix}Re ( \vec{b} ) \\ Im ( \vec{b} )\end{matrix} ) \qquad ( 2 \text{-} 36 )$$

The thus obtained equation system is real, the vector x is also real and can be considered directly as a consumer distribution of the consumer devices in the electric network.

It has been shown, however, that the approach according to Equation 2-36 does not yield any usable solution. Therefore, the approach in the real-valued representation of a complex equation system can be broadened, which is represented in Equation 2-37 below. The solving of this equation corresponds to the solution according to Equation 2-29. In contrast to Equation 2-29, the vector x that represents the consumer distribution of the consumer devices in the electric network in this case has twice as many components, whereby the first half of the components represents the real portion and the second half represents the imaginary portion of x. This representation makes possible a quick overview on the orders of magnitude of the imaginary portions of x.

$$( \begin{matrix}Re ( A ) & - Im ( A ) \\ Im ( A ) & Re ( A )\end{matrix} ) {x}^{\vec{\sim}} = ( \begin{matrix}Re ( \vec{b} ) \\ Im ( \vec{b} )\end{matrix} ) ( \begin{matrix}\begin{matrix}Re ( {x}_{1} ) \\ Re ( {x}_{2} ) \\ \\ \\ Re ( {x}_{n} )\end{matrix} \} = Re \vec{( x )} \\ \begin{matrix}Im ( {x}_{1} ) \\ Im ( {x}_{2} ) \\ ⋮ \\ Im ( {x}_{n} )\end{matrix} \} = Im \vec{( x )}\end{matrix} ) = {x}^{\vec{\sim}} \qquad ( 2 \text{-} 37 )$$

### 2.4.4 Numerical Optimization

Another possibility for solving the linear equation system is the application of a numerical optimization algorithm. The advantage consists in that the accuracy and the computing expense can be freely selected. The vector x that is to be varied can be as real or as complex as desired, depending on the implementation. The problem can be presented as a minimization problem:

$${\text{arg} min}_{x} {‖ A \vec{x} - \vec{b} ‖}_{2}^{2}$$

If F(x)=|A\vec{x}−\vec{b}| (2-39)

and the calculation of the Euclidean norm is executed, the minimization problem thus reads:

$${arg min}_{\vec{x}} {\sum }_{i = 1}^{m} {F}_{i}^{2} \vec{( x )} \qquad ( 2 \text{-} 40 )$$

Fᵢ(\vec{x})

is the deviation of a component in the equation F(x) from the exact solution of the equation system. The algorithm now determines the vector in which F(x) has a global minimum or a minimum within the subspace, which is produced from the specified limits for x.

Errors in the Numerical Process To distinguish the possible causes for improper solutions of numerical problems, the errors during transition to the numerical representation are divided into the following classes:
Data errors or input errors are caused by, e.g., noisy measurement values. Their effect on the solution cannot be avoided. Their influence on the result, however, must be examined and minimized. In this case, there are measuring errors when determining the network spectrum, i.e., in vector b.
Classification errors develop by the combination of consumer devices in classes. Here, the consumer devices of one class do not have exactly the same specific consumer spectrum. Rather, tolerances were defined, and all consumer devices within these tolerances were combined in this class.
Process errors arise from incomplete modeling of the problem, from discretization or from the finite number of steps in the iteration process.
Rounding errors result from the type of number representation and the limited number range in the computer itself. These errors are often underestimated. First, the absolute errors and the relative errors are defined:

$$\begin{matrix}{ɛ}_{k} = {x}_{k} - {\tilde{x}}_{k} ; {\tilde{x}}_{k} ⇔ N \ddot{a} herung ⇒ {δ}_{k} = \frac{{x}_{k} - {\tilde{x}}_{k}}{{x}_{k}} ⇒ rel . Fehler \\ \begin{matrix} [ approximation ] & [ relative errors ]\end{matrix}\end{matrix} \qquad ( 2 \text{-} 41 )$$

Condition of a Problem The effect of the data and the input errors is a function of the conditioning of the problem. A problem is referred to as well conditioned if small changes in the initial data also yield only small changes in the results. A problem is poorly conditioned, however, if small changes at the beginning lead to large deviations from the result. A poorly conditioned problem also cannot be satisfactorily resolved with a very good and numerically stable algorithm.

To assess the conditioning, condition numbers are defined. Linear equation systems as are used here are often very poorly conditioned. To assess errors, the condition number of the matrix A is defined as follows:

A malfunction Δx is produced by the malfunction Δb.

A(\vec{x}+Δ\vec{x})=\vec{b}+Δ\vec{b} [symbol] AΔ\vec{x}=Δ\vec{b} [symbol] Δ\vec{x}=pinv(A)Δ\vec{b} (2-42)

In this case, pinv(A)=A⁺ is the pseudoinverse of A.

The error Δx can be assessed with the aid of the matrix norms:

The relative error is then:

$$\frac{‖ Δ \vec{x} ‖}{‖ \vec{x} ‖} \leq ‖ {A}^{- 1} ‖ ‖ A ‖ \frac{‖ Δ \vec{b} ‖}{‖ \vec{b} ‖} \qquad ( 2 \text{-} 44 )$$

The factor ||A⁻¹||*||A|| is called a condition number of the matrix A, cond(A).

The value log₁₀(cond(A)) indicates, for example, the number of decimal points that are lost by rounding errors in solving the linear equation system. An indication of a poor conditioning of the problem is given, when:

$$cond ( A ) >> \frac{1}{\sqrt{eps}} \qquad ( 2 \text{-} 45 )$$

Here, the value eps is the interval from one number to the next largest producible number in a computing device (for example, the precision in the floating point representation).

Numerical Stability The numerical stability or instability, in contrast to the conditioning, describes the effect of the algorithm that is used on the result. In the floating-point arithmetic used in a computer, the numbers are often rounded during the calculation. This results in obliterating positions, which can lead to building up errors and numerical instability in the case of multistage calculations. This phenomenon is referred to as error propagation.

### 2.4.5 Improvement of the Condition of the LGS by Evaluation of Covariance

From linear algebra theory, it is evident that if two or more column vectors of one matrix come too close together in the linear sense, the condition number of the matrix is increased. This occurs in the case of consumer devices with almost linearly dependent consumer spectra.

Errors occurring in analysis often can be attributed to the high condition number of the consumer matrix that is formed from the consumer spectra. A high condition number indicates that the matrix has column vectors, which are close to the linear dependency.

To prevent column vectors from coming too close linearly, the matrix that consists of consumer spectra must be formed by those consumer devices that are significantly different. If the consumer devices are specified, a way must be found to consolidate the consumer devices in the consumer classes such that the consumer spectra within a consumer class have a maximum value of similarity; the consumer spectra of the consumer classes below one another, however, are significantly different.

The correlation coefficients of the consumer spectra can be readily depicted below one another by the covariance matrix R. The elements rᵢⱼ of the matrix R are then the empirical correlation coefficients of the consumer spectra and are a yardstick for the manifestation of the linear dependency of the consumer spectra on one another. The correlation of the consumer spectra significantly influences the conditioning of the consumer matrix A.

To calculate the covariance matrix R, the column vectors, i.e., the consumer spectra, from which matrix A removes the means, and the column vectors from which the means are removed are scaled with the reciprocal value of their Euclidean norm. The matrix U is produced.

The covariance matrix R is then defined as follows:

R=U^{H}U (2-46)

R thus obtains the following configuration:

$$R = ( \begin{matrix}1 & {r}_{12} & … & {r}_{1 n} \\ {r}_{21} & 1 & … & … \\ … & … & … & … \\ {r}_{m 1} & … & … & 1\end{matrix} ) \qquad ( 2 \text{-} 47 )$$

The normalized correlation coefficients are then calculated in the following way:

$${r}_{xy} = \frac{{\sum }_{i = 1}^{m} ( {a}_{ix} - {\overline{a}}_{x} ) ( {a}_{iy} - {\overline{a}}_{y} )}{\sqrt{{\sum }_{i = 1}^{m} {( {a}_{ix} - {\overline{a}}_{x} )}^{2} {\sum }_{i = 1}^{m} {( {a}_{iy} - {\overline{a}}_{y} )}^{2}}} \qquad ( 2 \text{-} 48 )$$

Here, aₓ and a_{y} can be the consumer spectra of matrix A, denoted as line vectors, and aᵢₓ and a_{iy} can be the components of the consumer spectra (complex amplitudes).

Correlation coefficients of less than 0.9 are generally referred to as sufficiently small.

Large correlation coefficients stand for a strongly pronounced linear correlation of the consumer spectra in question.

If a threshold value is defined and all consumer devices with correlation coefficients above this threshold value are consolidated in one consumer class, the size of the consumer matrix can be reduced, and the condition number of the thus created new matrix can be reduced.

The consumer spectrum of the consumer class is produced from consumer spectra of the consumer devices combined in the consumer class. If two consumer devices are combined in one consumer class, the consumer spectrum of the consumer class is produced by the consumer spectra of the two consumer devices being added and the resulting sum vector again being normalized to its first component, i.e., to the fundamental oscillation:

$${\vec{a}}_{mix} = \frac{1}{\vert {\vec{a}}_{11} + {\vec{a}}_{12} \vert} ( {\vec{a}}_{1} + {\vec{a}}_{2} ) \qquad ( 2 \text{-} 49 )$$

As a result, a mean of the consumer spectra is obtained. If another consumer is added to the consumer class, the new consumer spectrum of the consumer class is produced analogously.

In this way, great correlations between the consumer spectra that form the columns of matrix A can be reduced. The columns are now further removed from the linear dependency, and the space that is formed by the columns is less greatly distorted. The solving of the LGS is thus more robust and less susceptible to errors. Small measuring errors do not have significant effects on the measuring result because of the improved conditioning of the problem.

In principle, completely different approaches are also conceivable, in which inaccuracies as a result of poor matrix conditioning do not occur or play a less decisive role. Possible approaches for analysis of the model are, for example, signal-identification approaches from mobile communications, such as, e.g., the “maximum-likelihood detection” method, under certain circumstances expanded by a “lattice reduction” algorithm. Also, other frequency analysis processes, such as, e.g., the use of wavelets, are conceivable. Another preparation that consists of the diagnosis technique, the thus mentioned “blind source separation,” can be used, moreover, to improve the results.

### 2.4.6 Setting Up the Consumer Matrix A

It is suitable to classify the consumer devices of a partial network with the incorporation of the covariance matrix R. A conceivable way is to measure the consumer spectra from a large portion of the common consumer devices in a partial network and to form the matrix A with the consumer spectra as column vectors. If all spectra are found, the covariance matrix is calculated from the matrix A that is now large, and a threshold value for the empirical correlation coefficient is specified. From the test series that are examined here, a value of between 0.9 and 0.95 has proven to be effective for this threshold value.

The threshold value depends on the accuracy of the measuring technique that is used and the disrupting influences in a network. A value of below 0.9 is also conceivable, if, for example, it is to be different only between typical basic classes and linear consumer devices.

If all correlation coefficients above the threshold value in the covariance matrix are identified, in each case the geometric means are formed from all respective pairs or groups of these consumer devices and are defined as new consumer classes.

In turn, the covariance matrix is formed from this newly developing matrix. If, in addition, correlation coefficients are now above the specified threshold value, the averaging of these pairs and the formation of a new matrix are performed again. This is repeated iteratively often until the covariance matrix is free of correlation coefficients above the threshold value. The resulting consumer matrix then has the consumer spectra of the consumer classes that comprise the consumer devices.

Also, here, an analogous process is possible when using time signals.

The combination of the classes does not represent any disadvantage. The purpose of the process is to identify consumer devices in an electric network that are produced by the harmonic oscillations and to calculate their contribution to the overall distortion of the current plot in an electric network. If consumer devices have a very similar consumer spectrum, they also cause similar disruptions in the electric network. Thus, a consumer class provided from the combination of individual consumer devices is representative of the consumer devices contained in the consumer class for determining the feedback in an electric network.

### 2.5 Error Approximations and Simulation

In the case of calculations that are based on measuring values, an error approximation is indispensable to assess the plausibility of the results.

### 2.5.1 Evaluation of the Residual Error Vector

The residual error vector e provides information on how far the vector b lies outside the subspace of A (see FIG. 7). If b is a physical addition of the column vectors of A and is associated only with small measuring errors, the error vector e is very small compared to b and p. To examine the latter, the Euclidean norm of the vector e can be calculated by the LGS Ax=p being solved, the result vector x in e=b−Ax being used, and the norm of the vector e being calculated.

### 2.5.2 Weighted Fourier Synthesis

To control the results, the time plots produced from the consumer spectra are synthesized by means of inverse Fourier transformation and are superimposed corresponding to the solving of the LGS. This corresponds to an extensive control of the analysis. A synthesized time plot similar to the measured time plot can only take place if the column vectors reflect the true consumer structure and come close to the calculated consumer distribution of the consumer devices in the electric network of the actual consumer distribution. In this case, the control comprises the entire causal chain, including the measurement of the current signal of the electric network, the Fourier transformation, the detection of the consumer device, the classification of the consumer devices in consumer classes, and the solving of the LGS.

In FIG. 8, the diagram of the Fourier synthesis can be seen. The plots of the individual consumer classes are synthesized from the consumer spectra and are superimposed according to the determined consumer distribution:

$$f ( t ) = {\sum }_{j = 1}^{m} {\sum }_{i = 1}^{n} {x}_{j} {a}_{i } sin ( i ω + {ϕ}_{i} ) \qquad ( 2 \text{-} 50 )$$

Here, xⱼ refers to the weight of the j^{th} consumer spectrum, aᵢ refers to the i^{th} component of the j^{th} consumer spectrum, and i refers to the harmonics being considered.

It may be suitable to consider only nonstraight harmonics in the case of setting up an analysis of the network spectrum. In this case, the summation of the contributions of the harmonics in synthesis according to Equation 2-50 is carried out only over the nonstraight harmonics.

The network spectrum b of the electric network is used to solve the complex LGS. The synthesis is then carried out only from the consumer spectra deposited in the consumer matrix and the consumer distribution x corresponding to solving the LGS.

An influence factor of the quality of the synthesis is the phase position of the individual harmonics to which time plots for synthesis are added. If the consumer distribution x has an imaginary portion as a solution of the LGS, a phase error is thus present in the analysis. Since only the value of the consumer distribution x goes into the superposition in the synthesis according to Equation 2-50, the synthesis may thus be prone to error.

### 3 Application

In this section, measurements with a measuring system forming the device for identification of consumer devices in an electric network are described. These measurements are used for the verification of the mode of operation of the device and the process according to the invention.

In a first verification measurement, the current signal of the electric network of an office building with three stories and about 100 typically equipped offices was measured at one measuring point, the existing consumer devices on the network were detected separately, and the individual consumer spectra and the network spectrum were determined.

For this purpose, the consumer spectra of PC work positions, copiers on standby or in use, printers and elevators were measured. The consumer matrix was formed from these consumer spectra. Since the condition number of the thus formed matrix seemed large (in the range of about 80), the covariance matrix R was formed (Table 3-1), in which two correlation coefficients of over 0.95 were found. To improve the condition number of the consumer matrix, the consumer spectra were combined with the maximum correlation coefficient in a consumer class, namely the spectrum of the lighting system and the copier in use. The newly formed consumer device, reduced in its size by one column, had a considerably lower condition number (in the range of 20).

The new manifestations of the linear dependency of the column vectors representing the consumer spectra are clear by the formation of the covariance matrix of the consumer matrix (see Table 3-2). The newly formed covariance matrix does not have any correlation coefficients of greater than 0.95. The improvement of the conditioning can possibly have a negative effect on the individual correlation coefficients, however, as can be detected by, for example, the enlarged correlation coefficients between lighting and copiers on standby (previously 0.915 (Table 3-1), now 0.938 (Table 3-2)). Therefore, an iterative procedure in the setting-up of the consumer matrix for optimizing the covariance matrix may be advantageous.

TABLE 3-1
Covariance Matrix of the Consumer Structure M516

| | | | PC | Copiers | |
|---|---|---|---|---|---|
| Consumer | | PC Positions | Positions | on | Copiers in |
| Device | Lighting | (Old) | (New) | Standby | Use |
| Lighting | 1 | 0.50415 | 0.81882 | 0.91457 | 0.97463 |
| PC Position | — | 1 | 0.85688 | 0.57222 | 0.62842 |
| (Old) | | | | | |
| PC Position | — | — | 1 | 0.87909 | 0.91279 |
| (New) | | | | | |
| Copier on | — | — | — | 1 | 0.96068 |
| Standby | | | | | |

TABLE 3-2
Covariance Matrix of the Revised Consumer Matrix. Linear Class =
(Lighting + Copiers)

| Consumer | | PC Positions | PC Positions | Copiers on |
|---|---|---|---|---|
| Device | Linear | (Old) | (New) | Standby |
| Linear | 1 | 0.56869 | 0.8703 | 0.93893 |
| PC Positions | — | 1 | 0.85688 | 0.57222 |
| (Old) | | | | |
| PC Positions | — | — | 1 | 0.87909 |
| (New) | | | | |

Equation 3-1 shows the diagram of the equation system, and FIG. 9 shows the identified consumer distribution of the consumer devices in the electric network of the building. The result shows a linear portion of 90% (consumer device 1), the proportion of older PC work positions (consumer device 2) is about 5%, while the remaining 5% is distributed in proportions of copiers (consumer device 4) and modern PC work positions (consumer device 3).

$$\overbrace{( \begin{matrix}Spaltenvektor 1 & Spaltenvektor 2 & Spaltenvektor 3 \\ Beleuchtung & \ddot{a} ltere\_PC \text{-} & Kopierer \\ bestehend & Arbeitspl \ddot{a} tze & im \\ aus\_konvLsL & ⋯ & Stan dbybetrieb\end{matrix} \begin{matrix}Spaltenvektor 4 \\ mod erne \\ PC \text{-} Pl \ddot{a} tze\end{matrix} )}^{Verbrauchermatrix A 4} ( \begin{matrix}{x}_{1} \\ {x}_{2} \\ {x}_{3} \\ {x}_{4}\end{matrix} ) = \overbrace{( \begin{matrix}MessVekor\_b \\ von\_der \\ Haupverteilung \\ Keller\_M516 \_ 13.5 .2005\end{matrix} )}^{Messvektor\_b} \qquad ( 3 \text{-} 1 )$$

### [Key:]

Spaltenvektor=Column Vector

Beleuchtung bestehend aus=Lighting that Consists of

ältere PC-Arbeitsplätz=Older PC Work Position

Kopierer im Standbybetrieb=Copier on Standby

moderne PC−Plätze=Modern PC Positions

MessVekor [sic] von der Hauptverteilung=Measuring Vector of the Main Distribution

The complex statement realistically reflects the actual consumer distribution of the consumer devices in the electric network and is therefore to be preferred. The other statements prove to be clearly inaccurate based on the results in FIG. 9.

Below, measurements on an electric network with a largely unknown consumer structure are described.

Since a host of different consumer devices are generally involved in an electric network and it is not possible to consider all different consumer devices in the consumer matrix, an advance classification of the consumer devices in consumer classes is necessary.

An advantageous classification of the following consumer classes, which should be identified in the electric network, was based on this measurement:
1. Linear consumer devices without phase shift (pure ohmic consumer devices)
2. Linear consumer devices with inductive behavior such as engines and chokes
3. Consumer devices with a B2 rectifier behavior, e.g., PCs without power factor correction (PFC), economical lamps, power supplies of printers and other small devices
4. Consumer devices with a B6 rectifier behavior with heavy load, e.g., frequency converters in rated load operation
5. Controlled B6 power converters, e.g., frequency converters with power regulation.

The typical consumer spectra of these consumer devices were combined in a consumer matrix A. The linear equation system according to Equation 2-9 was then solved for various measured network spectra and thus determines the proportions of the consumer devices in the electric network.

The electric network that was examined was found in a five-story building with mainly laboratory devices. The consumer devices in this building were essentially lighting systems, ventilation systems, drying ovens, laboratory devices and PCs, whereby the exact consumer distribution and type of consumer device in the building was unknown. The current signal of the electric network of the building was measured at a measuring point that was arranged at the connecting point of the electric network of the building with an external energy supply network. The measured network spectrum is depicted in FIG. 10 in absolute measured values.

FIG. 11 shows the solutions of the linear equation system. The solution according to the complex statement indicates that, of the consumer devices in the electric network of the building, 45% are purely ohmic consumer devices (class 1 according to the above list), about 25% are linear consumer devices with an inductive portion (class 2) and about 23% are consumer devices with a B6 rectifier behavior.

FIG. 12 shows the time current signal (below) synthesized from the spectra of the consumer matrix and the calculated consumer distribution of the consumer devices in the electric network (according to the complex statement) and the current signal (above) measured at the measuring point of the electric network. The effective value of the normalized difference signal, which is formed by the difference between synthesized and measured current signals, is 0.08, while the effective value of the measured, normalized current signal is 0.72. This shows that both the consumer matrix that is used and the measurement and the analysis of the consumer distribution of the consumer devices in the electric network were detected or acquired with sufficient precision.

### 4 Interconnection of Consumer Devices

The harmonic oscillations produced by the consumer device in the current of an electric network stress the electric network greatly. With the aid of the device to identify consumer devices in an electric network, the harmonic oscillation content of the current and the voltage can be recorded, times with especially heavy loads can be detected, and the consumer devices in the electric network can be identified. In this way, noise sources can be determined, and this knowledge can be used to reduce the harmonic oscillation peaks, for example by operating times being altered or consumer devices being connected in a specific way.

### 4.1 Statistical Consideration of the Superpositions of Various Sources

Superposition of Harmonics and the Influence on the Distortion by Harmonic Oscillations By the interconnection of several harmonic oscillation generators, harmonics can result for constructive (in the same phase) or destructive superposition (in the opposite phase). Here, it is conceivable to consider either individual harmonics or to consider the distortion of the recorded current plot of an electric network (total harmonic distortion of the current plot: THD(I)) that is caused by the totality of the harmonics.

The total harmonic distortion of the n^{th} consumer device (THD(I)ₙ) in this case is defined as

$${THD ( I )}_{n} = \frac{\sqrt{{\sum }_{i = 2}^{50} {I}_{in}^{2}}}{{I}_{1 rms}} \qquad ( 4 \text{-} 1 )$$

whereby Iᵢₙ refers to the current amplitudes of the i^{th} harmonic of the n^{th} consumer device and I₁ᵣₘₛ represents the effective value of the fundamental oscillation.
Statistical Approach From wind power units in a wind park, it is known that the distortion of the current plot THD(I) depends on the number of systems being operated. In this case, the following connection was determined empirically:

$${THD ( I )}_{G} = \frac{{THD ( I )}_{n}}{\sqrt{n}} \qquad ( 4 \text{-} 2 )$$

For frequency converter units, the following applies for harmonic n<7:

$${I}_{n} = {\sum }_{i = 1}^{m} {I}_{{n}_{i}} \qquad ( 4 \text{-} 3 )$$

and for harmonic n>7:

$${I}_{n} = \sqrt{{\sum }_{i = 1}^{m} {I}_{{n}_{i}}^{2}} \qquad ( 4 \text{-} 4 )$$

Such guide values are important values in the planning and layout of systems with many consumer devices and other potential harmonic oscillation generators.

### 4.2 Deterministic Consideration of Superpositions of the Response of Different Consumer Devices

To study the superposition of various consumer spectra and their effect on the distortion of the current plot in an electric network, the THD(I) represents a superposition of two consumer devices, which represent noise sources producing distortions, compared to the mean THD(I) of these consumer devices and represented in one coefficient.

This coefficient is mentioned here based on the covariance evaluation “Ko-THDI-Factor.” If a complete consumer matrix is evaluated, a “KoTHDI matrix,” whose values indicate a respective weakening or enhancing of the harmonic oscillation content in the interconnection of the respectively related consumer devices, is produced. The KoTHDI matrix is symmetrical and has the following configuration:

$${R}_{THD ( I )} = ( \begin{matrix}1 & {r}_{{THD ( I )}_{12}} & … & {r}_{{THD ( I )}_{1 n}} \\ {r}_{{THD ( I )}_{21}} & 1 & & … \\ … & … & … & … \\ {r}_{{THD ( I )}_{m 1}} & … & … & 1\end{matrix} ) \qquad ( 4 \text{-} 5 )$$

The Ko-THDI factors can be calculated in the following way:

$${r}_{{THD ( I )}_{\ddot{v}}} = \frac{THD ( {I}_{i} + {I}_{j} )}{E ( THD ( {I}_{i} ) + THD ( {I}_{j} ) )} \qquad ( 4 \text{-} 6 )$$

E corresponds here to the statistical expectation value. As follows from Equation 4-6, any Ko-THDI factor is normalized and in the order of magnitude of 1. A value of less than 1 represents extinction of most harmonic oscillations, while a value of more than 1 produces a magnification by constructive superpositions of harmonics.

For example, in considering extinctions or enhancements, it is obvious to combine consumer devices with a B2 rectifier behavior and consumer devices with a B6 rectifier behavior B6, whose spectra in each case have very pronounced fifth and seventh harmonics that are in counter-phase to one another and thus are at least partially eliminated and produce a reduction of the THD(I).

FIG. 13 shows measured THD(I) values of eight different consumer devices. The identification of the consumer devices can be found from Table 4-1, which indicates the KoTHDI matrix of eight different consumer devices. The THD(I) values show a comparatively great deviation from one another, which ranges from a few percent in the “T5” consumer device (a fluorescent lamp) to values of more than 160% in the “Laptop” consumer device.

TABLE 4-1
Ko-THDI Matrix of the Consumer Matrix from the Laboratory

| Consumer | | | Economical | Incandescent | | | | |
|---|---|---|---|---|---|---|---|---|
| Device | T8 | T5 | Lamp | Lamp | FU | Motor | Laptop | Monitor |
| T8 | 1 | 1.0511 | 0.94596 | 0.97613 | 1.0733 | 1.3244 | 1.1949 | 1.0698 |
| T5 | 1.0511 | 1 | 1.1422 | 0.85927 | 0.96899 | 0.75796 | 0.97609 | 0.9709 |
| Economical | 0.94596 | 1.1422 | 1 | 1.0858 | 0.84085 | 1.418 | 0.9414 | 1.1922 |
| Lamp | | | | | | | | |
| Incandescent | 0.97613 | 0.85927 | 1.0858 | 1 | 0.99192 | 0.47613 | 0.98352 | 0.9829 |
| Lamp | | | | | | | | |
| FU | 1.0733 | 0.96899 | 0.84085 | 0.99192 | 1 | 1.0305 | 0.5475 | 0.8159 |
| Motor | 1.3244 | 0.75796 | 1.418 | 0.47613 | 1.0305 | 1 | 1.0235 | 0.91218 |
| Laptop | 1.1949 | 0.97609 | 0.9414 | 0.98352 | 0.5475 | 1.0235 | 1 | 0.89966 |
| Monitor | 1.0698 | 0.9709 | 1.1922 | 0.9829 | 0.8159 | 0.91218 | 0.89966 | 1 |

From Table 4-1, it follows that when connecting a consumer device formed by a frequency converter (FU) and a consumer device designed as a laptop, a considerable weakening of the THD(I) can be achieved. In this case, extinction in the harmonics is significant, such that the THD(I) is about 45% below the mean of the two individuals (this is indicated by the Ko-THDI factor).

The incorporation of the KoTHDI matrix can be helpful in a planning of an electric network. Thus, the most advantageous connection combinations could be determined from a pool of potential consumer devices for each linkage point. As can be detected in the matrix in Table 4-1, in principle a significant weakening of the distortion in an electric network can be reached by suitable connection of consumer devices.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosures of all applications, patents and publications, cited herein and of corresponding German application No. 102005047901.4, filed Sep. 30, 2005, and U.S. Provisional Application Ser. No. 60/721,969, filed Sep. 30, 2005, are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

### Legend

| | |
|---|---|
| 1 | Electric Network |
| 2a, 2b | Consumer Devices |
| 3 | Measuring Device for Measuring the Current Signal of the |
| | Electric Network |
| 4 | Measuring Device for Detecting the Consumer Spectra |
| 4′ | Analysis Device |
| 5 | Storage Medium |
| 6 | Data Analysis Device |
| 61 | Means for Performing a Fourier Transformation |
| 62, 63, 64 | Means for Generating the Model |
| 7 | Output Device |
| 8 | Compensation Device |
| E1-E4 | Consumer Devices |
| S1-S3 | Switches |
| MP8-MP11 | Measuring Points |

1. Device for identifying consumer devices (2a, 2b) in an electric network (1) with currents that can vary over time, with
a measuring device (3) for measuring at least one current signal on at least one measuring point (MP8) of the electric network (1),
a storage medium (5), in which at least one consumer signal, determined in advance, is stored,
a data analysis device (6) that
converts at least one measured current signal into a network signal,
automatically generates a model in which the network signal can be linked to at least one consumer device (2a, 2b) with at least one consumer signal that is stored in advance in the storage medium,
automatically analyzes the model for determining at least one consumer distribution of the consumer devices (2a, 2b) in the electric network (1), and
an output device (7) for at least one consumer distribution.

2. Device according to claim 1, characterized in that the measured current signal is a time signal.

3. Device according to claim 1, wherein the network signal of the electric network (1) and the consumer signals stored in the storage medium (5) produce time signals or frequency spectra.

4. Device according to claim 3, wherein the data analysis device (6) has means (61) by means of which a network spectrum that represents the network signal can be determined from the measured current signal of the electric network (1).

5. Device according to claim 4, wherein the data analysis device (6) for determining the network spectrum has means (61) for performing a Fourier transformation of the measured current signal of the electric network (1).

6. Device according to claim 3, wherein at least one consumer spectrum that represents a consumer signal or at least one time consumer signal is stored in the storage medium (5).

7. Device according to claim 3, wherein the data analysis device (6) provides means (62, 63, 64) for generating the model by means of which at least one consumer spectrum or at least one time consumer signal and the network spectrum or the time network signal in an equation system can be linked.

8. Device according to claim 1, characterized by a measuring device (4) for detecting at least one consumer signal of at least one consumer device (2a, 2b) that can be connected to the storage medium (5) for storing at least one consumer signal.

9. Device according to claim 8, wherein the measuring device (4) has a means for detecting at least one consumer signal, by means of which the current signal of at least one consumer device (2a, 2b) can be measured.

10. Device according to claim 9, wherein the measuring device (4) for detecting at least one consumer signal has means for performing a Fourier transformation of the measured current signal of at least one consumer device (2a, 2b) in order to determine a consumer spectrum that represents the consumer signal.

11. Device according to claim 8, wherein the measuring device (4) has means for detecting at least one consumer signal by means of which consumer devices (2a, 2b) can be classified in consumer classes based on the detected consumer signals.

12. Device according to claim 8, wherein the measuring device (4) for detecting at least one consumer signal has a mobile measuring device for measuring the current signal of a consumer device (2a, 2b).

13. Device according to at least claim 1, wherein the device (3-7) for identifying consumer devices (2a, 2b) in an electric network (1) is connected securely to the electric network (1).

14. Device according to claim 1, wherein the device (3-7) for identifying consumer devices (2a, 2b) in an electric network (1) is integrated in a measuring device and has connections for connecting to at least one electric consumer device (2a, 2b) and one electric network (1).

15. Device according to claim 1, characterized by a compensation device (8) that works together with the data analysis device (6) for compensation of a distortion of currents and voltages in the electric network (1) such that the currents and voltages of the electric network (1) are matched in a desired way.

16. Device according to claim 1, wherein the electric network represents an energy supply network (1), whereby the device (3-7) determines the consumer distribution of consumer devices (2a, 2b) in the energy supply network (1) and based on the consumer distribution of the consumer devices (2a, 2b), the current and the voltage that adjoin a feeder point of the energy supply network (1) are varied.

17. Device according to claim 1, wherein the electric network (1) is part of a system that has electric consumer devices (2a, 2b), whereby the electric consumer devices (2a, 2b) of the system can be monitored and/or controlled by means of the device (3-7).

18. Process for driving the device (3-7) according to claim 1, with the following steps:
Measurement of at least one current signal of an electric network (1) at least one measuring point (MP8),
Determination of a network signal that consists of at least one measured current signal of the electric network (1),
Automatic generation of a model in which the network signal and at least one consumer signal, detected in advance, of at least one consumer device (2a, 2b) are linked to one another,
Automatic analysis of the model for identifying the consumer devices (2a, 2b) in the electric network (1),
Storage and/or output of a discrete consumer distribution in the electric network (1).

19. Process according to claim 18, wherein the consumer signal of at least one consumer device (2a, 2b) represents a vector that is arranged in a consumer matrix for generating the model.

20. Process according to claim 19, wherein for generating the model that consists of the consumer matrix and a measured network signal, an equation system is formed, which is analyzed in the electric network (1) for the identification of the consumer devices (2a, 2b).

21. Process according to claim 18, wherein first the consumer signal of at least one consumer device (2a, 2b) is acquired and is stored in a storage medium (5).

22. Process according to claim 21, wherein to determine the consumer signal of at least one consumer device (2a, 2b), the current signal of at least one consumer device (2a, 2b) is first measured separately.

23. Process according to claim 18, wherein for detecting at least one consumer signal of at least one consumer device (2a, 2b), different network signals are detected at different times, and at least one consumer signal of at least one consumer device (2a, 2b) is determined from the different, detected network signals.

24. Process according to claim 23, wherein at least one consumer signal of at least one consumer device (2a, 2b) is determined by an eigenvalue analysis or singular value separation of the varying detected network signals arranged in a matrix.

25. Process according to claim 23, wherein the detection of at least one consumer signal is performed repeatedly, and the detected consumer signal is matched iteratively and/or stored in a new state.

26. Process according to claim 20, wherein consumer devices (2a, 2b) with similar consumer signals are assigned to a consumer class, whereby the consumer signal of the consumer class is produced from the consumer signals of the consumer devices (2a, 2b) combined in the consumer class.

27. Process according to claim 26, wherein the similar consumer signals have a normalized correlation coefficient of greater than 0.9, in particular 0.95.

28. Process according to claim 26, wherein the classification of the consumer devices (2a, 2b) in consumer classes is carried out iteratively and is matched adaptively by measurements staggered in time.

29. Process according to claim 20, wherein the consumer signal of at least one consumer device (2a, 2b) produces a consumer spectrum, and the network signal of the electric network (1) produces a network spectrum, whereby in the consumer spectrum and in the network spectrum, the amplitudes of the harmonic oscillations of the current signal or at least one consumer device (2a, 2b) or the electric network (1) are stored.

30. Process according to claim 29, wherein in the model, only the nonstraight harmonic oscillations of at least one consumer spectrum and the network spectrum are considered.

31. Process according to claim 30, wherein based on the number of consumer devices (2a, 2b) and the number of the harmonic oscillations detected in the consumer spectra and the network spectrum, an under-determined, a determined or an over-determined equation system is produced.
